(19) United States
(12) Patent Application Publication
(10) Pub. No.: US 2002/0118075 A1
(43) Pub. Date: Aug. 29, 2002

(54) Impedance matching circuit and antenna apparatus using the same

(75) Inventors: Tetsu Ohwada, Tokyo (JP); Moriyasu Miyazaki, Tokyo (JP); Tamotsu Nishino, Tokyo (JP); Tsutomu Endo, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 09/905,897

(22) Filed: Jul. 17, 2001

Related U.S. Application Data
(63) Continuation of application No. PCT/JP99/07030, filed on Dec. 15, 1999.

(51) Int. Cl. H03H 7/38

(52) U.S. Cl. 333/32; 333/33; 343/860

(57) ABSTRACT

One matching circuit (8-2) comprises a transmission line (6b) of a predetermined electrical length and a parallel resonance circuit (5) connected in parallel with the transmission line. The resonance circuit has a resonant frequency f2 and a predetermined susceptance at a frequency f1 lower than the frequency f2. ANother matching circuit (8-1) comprises a transmission line (6a) of a predetermined electrical length and a capacitor element (b 3a) connected in series with the transmission line between an input terminal (2) of an antenna (1) and the matching circuit (8-2) so that the input impedence of the antenna at the frequency f2 may match the characteristic impedance of an external circuit (10).

### CROSS-REFERENCE TO THE RELATED APPLICATION

This application is a continuation of International Application No. PCT/JP99/07030, whose international filing date is Dec. 15, 1999, the disclosures of which Application are incorporated by reference herein. The present application has not been published in English.

### BACKGROUND OF THE INVENTION

1. Field of the Invention

The present invention relates to an impedance matching circuit applied to an antenna apparatus mainly used for a VHF band, an UHF band, a microwave band, and a milliwave band, and an antenna apparatus, to which the impedance matching circuit is applied.

2. Description of the Related Art

FIG. 1 is a perspective view of an antenna apparatus including a conventional impedance matching circuit disclosed in, for example Japanese Patent Application Laid-Open No. 1997-307331; FIG. 2 a circuit view of the antenna apparatus shown in FIG. 1; and FIG. 3 an expanded view of an antenna used in the antenna apparatus. In each of these drawings, a reference numeral 1 denotes an antenna composed of a chip antenna similar to, for example, the one shown in FIG. 3; 2 an input terminal of the antenna 1; 1-2 a radiation conductor of the antenna l; and 12-2 a ceramic block for covering the outer part of the radiation conductor 1-2.

A reference numeral 3a denotes a capacity-variable capacitance device; 3b a capacity-fixed capacitance device; 4a an inductance device; and 7 an impedance matching circuit composed of these devices. For the capacity-variable capacitance device 3a, an active device such as a varactor diode or the like is used.

A reference numeral 9 denotes an input terminal of the antenna apparatus; and 10 an external circuit such as a power source circuit, an RF circuit or the like, connected to the input terminal 9. A reference numeral 12 denotes a dielectric substrate for loading the antenna 1, and the impedance matching circuit 7; and 13a, 13b and 13c ground conductors provided in the front surface and the rear side of the dielectric substrate 12.

In addition, FIG. 4 shows an equivalent circuit of the antenna 1. In FIG. 4, a reference numeral 2 denotes the input terminal of the antenna 1; 3c a capacitance device; 4-2 a resistor; and 4b an inductance device. In other words, the antenna 1 is a single resonance antenna composed of the capacitance device 3c, the resistor 4-2 and the inductance device 4b, which are connected in series, and operated similarly to a series-resonant circuit.

Next, the operation of the antenna apparatus thus constructed will be described.

For example, it is assumed that at a frequency f1, the antenna 1 has a value of R1+jX1 (R1, and X1 are both positive) as an input impedance in the input terminal 2. In this case, at the impedance matching circuit 7 shown in FIG. 2, first, a capacity value of the capacitance device 3a is adjusted by changing a bias voltage applied to the varactor diode or the like constituting the capacitor device 3a, and a reactance component X1 of the input impedance is set equal to 0. Then, by using an impedance transforming function, which is obtained by properly combining a value of the serially disposed inductance device 4a with a value of the parallely disposed capacitance device 3b, a resistance component R1 of the input impedance is matched with characteristic impedance of the external circuit 10. Accordingly, at the frequency f1, the generation of reflected waves can be reduced, making it possible to efficiently operate the antenna 1 from the external circuit 10.

It is now assumed that at a frequency f2 different from the frequency f1, the antenna 1 has a value of R2+jX2 (R2, and X2 are both positive) as input impedance in the input terminal 2, and there is no big difference between a value of the resistance component R2 and a value of the resistance component R1. In this case, a capacity value is changed to a proper value by changing a bias voltage applied to the capacitance device 3a. In this way, as in the case of the frequency f1, the input impedance can be closely matched with the characteristic impedance of the external circuit 10. Thus, in the antenna apparatus shown in FIG. 1, the antenna 1 can be efficiently operated at a plurality of frequencies.

Other documents are available, describing the impedance matching circuit connected to the input/output of an amplifier. For example, Japanese Patent Application Laid-Open No. 1997-326648 discloses a technology developed in accordance with a broader band of the amplifier to carry out impedance matching by using open and short stubs. In this example, the two stubs are treated independently of each other, and a length of the short stub is set equal to 1/4 of a wavelength of a higher one of two frequencies to be matched. The combination of the two stubs is regarded as a parallel-resonant circuit and, at one of the two frequencies to be matched, the resonant circuit performs parallel resonance.

In a separate application to this application, the present inventor has filed a patent application for the non-contact power supply of a helical antenna (PCT/JP99/03453).

As the conventional antenna apparatus is constructed in the foregoing manner, in order to carry out impedance matching at a plurality of frequencies, a capacity of the capacitance device 3a is made variable, and this capacity is adjusted to take a proper value. If an active device such as a varactor diode or the like is used, the adjustment of the capacity value is carried out by providing a bias circuit, and adjusting a bias voltage applied to the varactor diode or the like. It is thus necessary to provide a control circuit in addition to the bias circuit, making a circuitry complex. The complexity of the circuitry and the increase in the number of components have caused an increase in manufacturing costs, and resulted in higher power consumption. These pose serious problems especially for a transportable radio terminal such as a portable telephone set or the like.

Furthermore, in the case of the conventional impedance matching circuit 7, impedance matching can be carried out only for the antenna 1 having a specific input impedance characteristic. Thus, the range of application has been limited.

The present invention was made to solve the foregoing problems. Objects of the invention are to provide an impedance matching circuit for efficiently operating single resonance antennas of various types at two frequency bands or a broader frequency band, and an antenna apparatus, both with simple circuitry and at low costs.

“Single resonance antenna” referred to in the specification is a generic term for the antenna of a broad type, and is in no way limited to any particular antenna.

### SUMMARY OF THE INVENTION

In accordance with the present invention, an impedance matching circuit is provided, comprising: a transmission line having a predetermined electrical length, connected to an antenna; and a second matching circuit including a parallel-resonant circuit connected in parallel with the transmission line, and adapted to resonate at a frequency f2 and exhibit a predetermined susceptance value at a lower frequency f1. Thus, in the antenna that has already been matched for impedance at the frequency f2, impedance can also be matched with the characteristic impedance Z0 of an external circuit at the frequency f1 while the impedance matched state of the input terminal of the antenna at the frequency f2 is maintained. As a result, circuitry can be simplified, and a circuit size can be reduced. In addition, since the control circuit of an active device for constituting the impedance matching circuit is unnecessary, a compact, low-cost and highly reliable antenna apparatus can be provided. Since there are no active devices, it is possible to reduce power consumed by the matching circuit for performing impedance matching at two frequency bands.

According to the present invention, the impedance matching circuit further comprises: a first matching circuit interposed between the input terminal of the antenna and the second matching circuit to match the input impedance of the antenna and the characteristic impedance of the external circuit with each other at the frequency f2. Thus, even in an antenna in which an impedance matching has not been performed yet at the frequency f2, impedance can be matched with the characteristic impedance Z0 not only at the frequency f2 but also at the frequency f1. In addition, since the newly disposed first matching circuit carries out impedance matching for a single frequency, generally, the circuit can be easily constructed only by a passive device and a transmission line. Thus, according to the invention, impedance matching can be carried out at two frequency bands only by the passive device without using any active devices. As a result, the circuitry of the impedance matching circuit can be simplified and, since the control circuit of an active device is unnecessary, a compact, low-cost and highly reliable antenna apparatus can be provided. Moreover, since there are no active devices, it is possible to reduce power consumed by the impedance matching circuit for performing impedance matching at the two frequency bands.

According to the present invention, the first matching circuit includes a transmission line having a predetermined electrical length, and a capacitance device connected in series to the transmission line. Thus, since the entire impedance matching circuit comprises the capacitance device, an inductance device and the transmission line, the circuitry can be further simplified, and a compact and low-cost impedance matching circuit can be manufactured.

According to the present invention, the first matching circuit includes a transmission line having a predetermined electrical length, and an inductance device connected in series to the transmission line. Thus, since the entire impedance matching circuit comprises the capacitance device, the inductance device and the transmission line, the circuitry can be simplified, and a compact and low-cost impedance matching circuit can be manufactured. Moreover, since the series inductance device is used in the first matching circuit, the circuit can be made compact when impedance matching is carried out for the antenna exhibiting an input impedance characteristic of high impedance.

According to the present invention, the first matching circuit includes a transmission line having a predetermined electrical length, and a parallel-resonant circuit connected in parallel with the transmission line, and adapted to resonate at the frequency f1 and exhibit a predetermined susceptance value at the frequency f2. Thus, it is possible to provide an impedance matching circuit capable of performing impedance matching at two frequency bands for an antenna exhibiting any impedance matching characteristics.

According to the present invention, the second matching circuit includes a transmission line having a predetermined electrical length, and short and open stubs connected to the transmission line, and electrical lengths of the short and open stubs are set such that a sum of the electrical lengths of the short and open stubs can be roughly 1/4, or an odd number multiple, of a wavelength at the frequency f2, and a sum of susceptance values of the short and open stubs can take a predetermined susceptance value at the frequency f1. Thus, in the antenna that has already been matched for impedance at the frequency f2, impedance can be matched with the characteristic impedance Z0 at the frequency f1 while the impedance matched state of the input terminal of the antenna at the frequency f2 is maintained, and the parallel-resonant circuit is constructed by combining the short and open stubs. As a result, compared with an arrangement using chip components, an impedance matching circuit having smaller losses can be provided, and the reduced number of chip components enables manufacturing costs to be lowered.

According to the present invention, a first matching circuit is interposed between the input terminal of the antenna and the second matching circuit including the parallel-resonant circuit having the short and open stubs to match the input impedance of the antenna and the characteristic impedance of the external circuit with each other at the frequency f2. The first matching circuit includes a transmission line having a predetermined electrical length, and a reactance device connected in series to the transmission line. Thus, even in an antenna in which an impedance matching has not been performed at the frequency f2, impedance can be matched with the characteristic impedance Z0 not only at the frequency f2 but also at the frequency f1. In addition, since the parallel-resonant circuit is constructed by combining the short and open stubs, compared with the case of using chip components, losses for the impedance matching circuit can be reduced more. The reduced number of chip components enables the impedance matching circuit to be constructed at lower costs.

According to the present invention, the transmission lines of the first and second matching circuits, and the short and open stubs are constructed by using a planar transmission line. For the reactance device of the first matching circuit, a capacitance device having a conductor pattern, such as an interdigital capacitor or the like, is used. Thus, without using any chip devices, the circuit can be constructed only by patterning the planar transmission line such as a micro strip line or the like, making it possible to manufacture an impedance matching circuit at low costs. In addition, since the capacitance device having a given capacitance value can be manufactured accurately and easily, an impedance matching circuit having a better characteristic can be provided.

According to the present invention, the first matching circuit includes a transmission line having a predetermined electrical length, and short and open stubs connected to the transmission line. Electrical lengths of the short and open stubs are set such that a sum of the electrical lengths of the short and open stubs can be roughly 1/4, or an odd number multiple, of a wavelength at the frequency f1, and a sum of susceptance values of the short and open stubs can take a predetermined susceptance value at the frequency f2. Thus, it is possible to provide an impedance matching circuit capable of performing impedance matching at two frequency bands for an antenna exhibiting any impedance characteristics.

In accordance with invention, the second matching circuit includes a transmission line having a predetermined electrical length, and first and second open stubs connected to the transmission line. Electrical lengths of the first and second open stubs are set such that a sum of the electrical lengths of the first and second open stubs can be roughly 1/2, or an integral multiple, of a wavelength at the frequency f2, and a sum of susceptance values of the first and second open stubs can take a predetermined susceptance value at the frequency f1. Thus, in the antenna that has already been matched for impedance at the frequency f2, impedance can also be matched with the characteristic impedance Z0 at the frequency f1 while the impedance matched state of the input terminal of the antenna at the frequency f2 is maintained. Moreover, since the parallel-resonant circuit is constructed without using any short stubs, the necessity of through-holes is eliminated to simplify manufacturing, making it possible to manufacture an impedance matching circuit at low costs.

According to the present invention, a first matching circuit is interposed between the input terminal of the antenna and the second matching circuit having the first and second open stubs to match the input impedance of the antenna and the characteristic impedance of the external circuit with each other at the frequency f2. The first matching circuit includes a transmission line having a predetermined electrical length, and a reactance device connected to the transmission line. Thus, even in an antenna in which an impedance matching has not been performed yet at the frequency f2, impedance can be matched with the characteristic impedance Z0 not only at the frequency f2 but also at the frequency f1. Moreover, since the parallel-resonant circuit is constructed without using any short stubs, the necessity of through-holes is eliminated, making it possible to manufacture an impedance matching circuit easily and at low costs.

According to the present invention, the transmission lines of the first and second matching circuits, and the first and second open stubs are constructed by using a planar transmission line such as a micro strip line or the like. For the reactance device of the first matching circuit, a capacitance device having a conductor pattern, such as an interdigital capacitor or the like, is used. Thus, without using any chip devices, the circuit can be constructed only by patterning the planar transmission line such as a micro strip line or the like. It is therefore possible to manufacture an impedance matching circuit at low costs. In addition, since the capacitance device having a given capacitance value can be manufactured accurately and easily, an impedance matching circuit having a better characteristic can be provided.

According to the present invention, the first matching circuit includes a transmission line having a predetermined electrical length, first and second open stubs connected to the transmission line. Electrical lengths of the first and second open stubs are set such that a sum of the electrical lengths of the first and second open stubs can be roughly 1/2, or an integral multiple, of a wavelength at the frequency f1, and a sum of susceptance values of the first and second open stubs can take a predetermined susceptance value at the frequency f2. Thus, it is possible to provide an impedance matching circuit capable of performing impedance matching at two frequency bands for an antenna exhibiting any impedance characteristics.

According to the present invention, a first matching circuit includes an impedance transformer provided to match the input impedance of the antenna and the characteristic impedance of the external circuit with each other at the frequency f2. Thus, impedance matching for a micro strip antenna can be carried out by the impedance matching circuit having simple and low-cost circuitry.

According to the present invention, an impedance matching circuit is provided, comprising: a hollow cylindrical dielectric; a ground conductor provided in the cylindrical inner surface of the cylindrical dielectric; a plurality of first matching circuits disposed in the cylindrical outer surface of the cylindrical dielectric to perform impedance matching at a frequency f2, each of the first matching circuits including a transmission line, and a capacitance device; and a plurality of second matching circuits respectively connected to the plurality of first matching circuits, each of the second matching circuits including a transmission line, and a parallel-resonant circuit adapted to resonate at the frequency f2 and exhibit a predetermined susceptance value at a frequency f1. The first and second matching circuits are constructed by a strip conductor constituting a micro strip line with the cylindrical dielectric and the ground conductor. Thus, a plurality of impedance matching circuits can be constructed on the cylindrical dielectric only by patterning the strip conductor. It is therefore possible to provide an impedance matching circuit which facilitates low-cost manufacturing.

According to the present invention, the parallel-resonant circuit of each second matching circuit includes short and open stubs connected to roughly the same place of the transmission line. Thus, a plurality of impedance matching circuits can be constructed on the cylindrical dielectric only by pattering the strip conductor, making it possible to provide an impedance matching circuit which facilitates low-cost manufacturing.

According to the present invention, the parallel-resonant circuit of each second matching circuit includes first and second open stubs connected to roughly the same place of the transmission line. Thus, the necessity of a through-hole for forming a short stub is eliminated to enable an impedance matching circuit to be manufactured more easily.

According to the present invention, an antenna apparatus is provided, comprising: a hollow cylindrical dielectric; helical radiation devices amounting to N in number, including a strip-like conductor and helically wound on the cylindrical outer surface of the cylindrical dielectric; a ground conductor provided in a region, the region being a part of a cylindrical inner surface of the cylindrical dielectric; a micro strip line constituted of the cylindrical dielectric, the ground conductor and a strip conductor; impedance matching circuits amounting to N in number, respectively corresponding to the helical radiation devices, and disposed in the outer surface of the cylindrical dielectric, each of the impedance matching circuits including first and second matching circuits; and an N-distribution circuit. The impedance matching circuits amounting to N in number are connected to the input terminal of the antenna apparatus according to required distribution amplitude and phase characteristics. Thus, the helical radiation devices, the impedance matching circuits respectively amounting to N in number and the N-distribution circuit are integrally provided in the outer surface of the cylindrical dielectric, enabling a radio terminal apparatus including the antenna apparatus to be made compact. Moreover, the number of helical radiation devices is N, and the number of input terminals that the antenna has is also N. However, the integral formation of the N-distribution circuit necessitates only one input terminal for connection with the external circuit, making it possible to simplify the structure of interface with the external circuit. Therefore, not only the low-cost assembling of the antenna apparatus can be facilitated, but also its reliability can be enhanced.

According to the present invention, the parallel-resonant circuit of each impedance matching circuit includes short and open stubs connected to roughly the same place of the transmission line. Thus, a plurality of impedance matching circuits can be constructed on the cylindrical dielectric only by patterning the strip conductor, enabling an antenna apparatus to be manufactured easily and at low costs.

According to the present invention, the parallel-resonant circuit of each impedance matching circuit includes first and second open stubs connected to roughly the same place of the transmission line. Thus, the necessity of a through-hole for forming a short stub is eliminated, making is possible to provide an antenna apparatus which is manufactured more easily.

### BRIEF DESCRIPTION OF THE DRAWINGS

FIG. 1 is a perspective view showing an antenna apparatus including a conventional impedance matching circuit.

FIG. 2 is a circuit view of the antenna apparatus shown in FIG. 1.

FIG. 3 is an expanded view of an antenna used in the antenna apparatus shown in FIG. 1.

FIG. 4 is a circuit view showing an equivalent circuit of the antenna shown in FIG. 3.

FIG. 5 is a perspective view showing an antenna apparatus according to a first embodiment of the present invention.

FIG. 6 is an upper surface view of the antenna apparatus shown in FIG. 5.

FIG. 7 is a circuit view of the antenna apparatus shown in FIG. 5.

FIG. 8 is Smith chart showing an input impedance characteristic of an antenna when an antenna side is seen from a node A shown in the circuit view of FIG. 7.

FIG. 9 is Smith chart showing a characteristic when the antenna side is seen from a node B shown in the circuit view of FIG. 7.

FIG. 10 is Smith chart showing a characteristic when the antenna side is seen from a node C shown in the circuit view of FIG. 7.

FIG. 11 is Smith chart showing a characteristic when the antenna side is seen from a node D shown in the circuit view of FIG. 7.

FIG. 12 is a view showing a susceptance frequency characteristic of a parallel-resonant circuit near a resonance frequency.

FIG. 13 is Smith chart showing a characteristic when the antenna side is seen from a node E shown in the circuit view of FIG. 7.

FIG. 14 is a view showing a frequency characteristic of a return loss of the antenna from the node E shown in the circuit view of FIG. 7.

FIG. 15 is a perspective view showing an antenna apparatus according to a second embodiment of the invention.

FIG. 16 is an upper surface view of the antenna apparatus shown in FIG. 15.

FIG. 17 is a circuit view of the antenna apparatus shown in FIG. 15.

FIG. 18 is Smith chart showing an input impedance characteristic of an antenna when an antenna side is seen from a node A shown in the circuit view of FIG. 17.

FIG. 19 is Smith chart showing a characteristic when the antenna side is seen from a node B shown in the circuit view of FIG. 17.

FIG. 20 is Smith chart showing a characteristic when the antenna side is seen from a node C shown in the circuit view of FIG. 17.

FIG. 21 is a circuit view showing an antenna apparatus according to a third embodiment of the invention.

FIG. 22 is a circuit view showing an antenna apparatus according to a fourth embodiment of the invention.

FIG. 23 is a perspective view showing an antenna apparatus according to a fifth embodiment of the invention.

FIG. 24 is an upper surface view of the antenna apparatus shown in FIG. 23.

FIG. 25 is a circuit view of the antenna apparatus shown in FIG. 23.

FIG. 26 is a perspective view showing an antenna apparatus according to a sixth embodiment of the invention.

FIG. 27 is an upper surface view of the antenna apparatus shown in FIG. 26.

FIG. 28 is a perspective view showing an antenna apparatus according to a seventh embodiment of the invention.

FIG. 29 is an upper surface view of the antenna apparatus shown in FIG. 28.

FIG. 30 is a circuit view of the antenna apparatus shown in FIG. 28.

FIG. 31 is a perspective view showing an antenna apparatus according to an eighth embodiment of the invention.

FIG. 32 is an upper surface view of the antenna apparatus shown in FIG. 31.

FIG. 33 is a circuit view of the antenna apparatus shown in FIG. 31.

FIG. 34 is Smith chart showing an input impedance characteristic of an antenna when an antenna side is seen from a node A shown in the circuit view of FIG. 33.

FIG. 35 is Smith chart showing a characteristic when the antenna side is seen from a node C shown in the circuit view of FIG. 33.

FIG. 36 is a perspective view showing an antenna apparatus according to a ninth embodiment of the invention.

FIG. 37 is a development showing a cylindrical dielectric outer surface of the antenna apparatus shown in FIG. 36.

FIG. 38 is a development showing a cylindrical dielectric inner surface of the antenna apparatus shown in FIG. 36.

FIG. 39 is an expanded view showing a strip conductor pattern of a matching circuit portion of the antenna apparatus shown in FIG. 37.

FIG. 40 is a circuit view of the antenna apparatus of the ninth embodiment.

FIG. 41 is a view showing a frequency characteristic of a return loss when an antenna side is seen from a node F shown in FIG. 40.

FIG. 42 is a perspective view showing an antenna apparatus according to a tenth embodiment of the invention.

FIG. 43 is a development showing a cylindrical dielectric outer surface of the antenna apparatus shown in FIG. 42.

FIG. 44 is a development showing a cylindrical dielectric inner surface of the antenna apparatus shown in FIG. 42.

FIG. 45 is an expanded view showing a strip conductor pattern of a matching circuit portion of the antenna apparatus shown in FIG. 43.

FIG. 46 is a circuit view of the antenna apparatus of the tenth embodiment.

### DETAILED DESCRIPTION OF THE PREFERRED EMBODIMENTS

Next, the present invention will be described more in detail based on the preferred embodiments with reference to the accompanying drawings.

(First Embodiment)

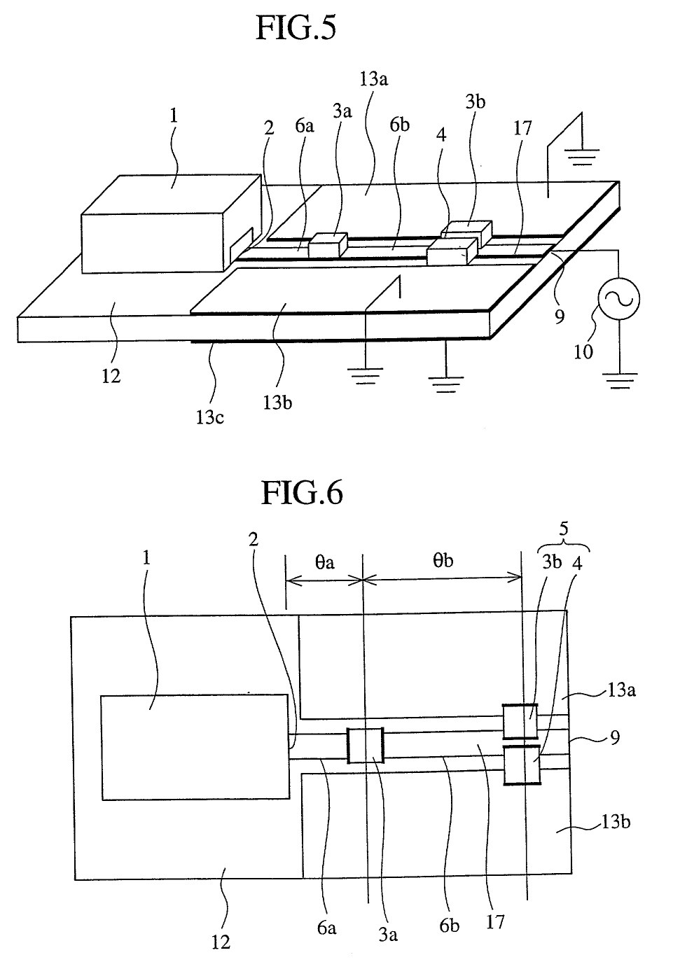

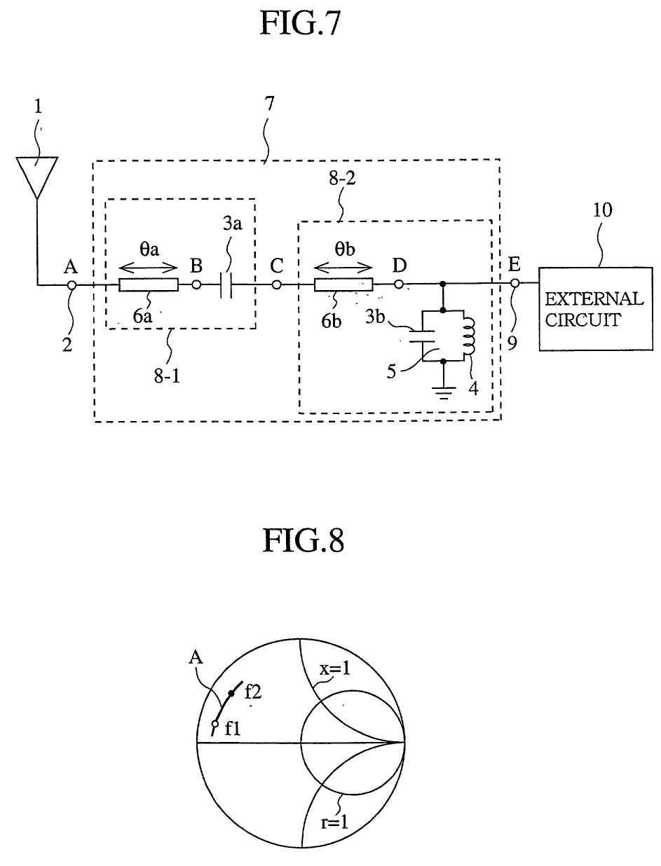

FIG. 5 is a perspective view showing an antenna apparatus according to the first embodiment of the invention; FIG. 6 an upper surface view of the antenna apparatus shown in FIG. 5; and FIG. 7 a circuit view of the antenna apparatus. The antenna apparatus shown in FIGS. 5 to 7 comprises, in combination, a commercially available chip antenna used for a compact radio terminal such as a portable telephone set or the like, and an impedance matching circuit for operating the chip antenna at two frequency bands. The impedance matching circuit is constructed by mounting a capacitance device such as a chip device, and a reactance device such as an inductance device on a coplanar line.

In FIGS. 5 to 7, a reference numeral 1 denotes an antenna equivalent to the above-described chip antenna; 2 an input terminal of the antenna 1; 12 a dielectric substrate for loading the antenna 1 and a later-described impedance matching circuit 7; 13a and 13b ground conductors formed on the surface of the dielectric substrate 12; 13c also a ground conductor formed on the rear side thereof; 17 a coplanar line center conductor constituting a coplanar line as a power supply line for the antenna 1 together with the dielectric substrate 12 and the ground conductors 13a to 13c; 10 an external circuit such as a power source circuit, an RF circuit or the like; and 9 an input terminal of the antenna apparatus, to which the external circuit 10 is connected.

A reference numeral 6a denotes a transmission line composed of the coplanar line, and having a predetermined electrical length θa at a frequency f2; 3a a capacitance device such as a chip capacitor provided on a gap formed in the coplanar line center conductor 17, and serially mounted as a circuit; 6b a transmission line composed of the coplanar line, and having a predetermined electrical length θb at a frequency f1; 3b a capacitance device such as a chip capacitor connected and mounted between the coplanar center conductor 17 and the ground conductor 13a; 4 an inductance device such as a chip inductor connected and mounted between the coplanar center conductor 17 and the ground conductor 13b; and 5 a parallel-resonant circuit constructed by mounting the capacitance device 3b and the inductance device 4 on the same place as that for the coplanar center conductor 17.

In this case, device values of the inductance device 4 and the capacitance device 3b constituting the parallel-resonant circuit 5 are selected such that the parallel-resonant circuit 5 can resonate at the frequency f2, and exhibit a predetermined susceptance value at the frequency f1. In matching with this selection, a required value is selected for the electrical length θb of the transmission line 6b.

A reference numeral 8-1 denotes a first matching circuit composed of the transmission line 6a and the capacitance device 3a, and adapted to carry out impedance matching for the antenna 1 at the frequency f2; and 8-2 a second matching circuit composed of the transmission line 6b and the parallel-resonant circuit 5, and adapted to carry out impedance matching at the frequency f1. As described above, the reference numeral 7 denotes the impedance matching circuit composed of the first and second matching circuits 8-1 and 8-2, and adapted to carry out impedance matching at the two frequencies f1 and f2.

In the circuit view of FIG. 7, circuit nodes A to E are shown for description of the operation made later.

Next, description will be made of the operation of the antenna apparatus of the first embodiment constructed in the foregoing manner.

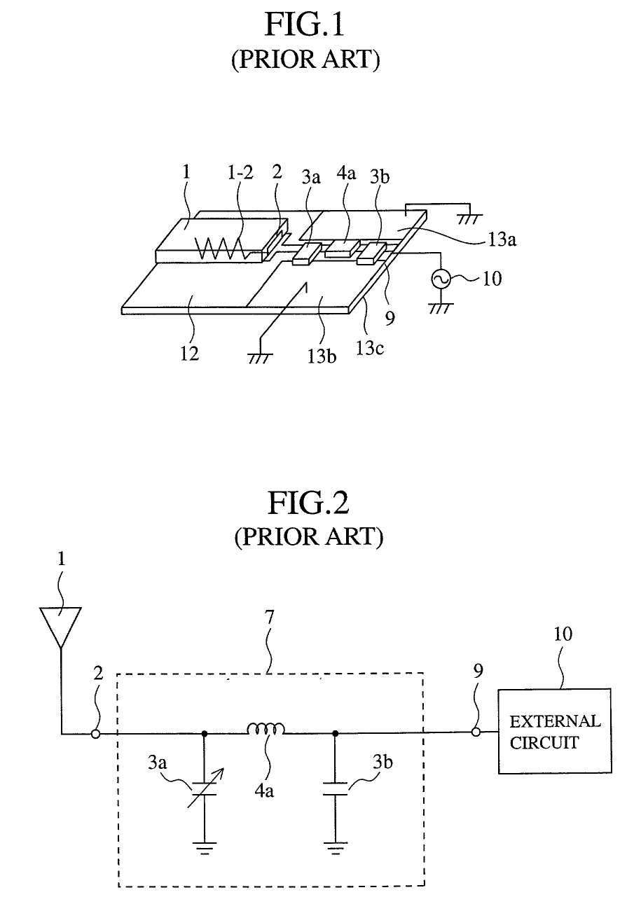

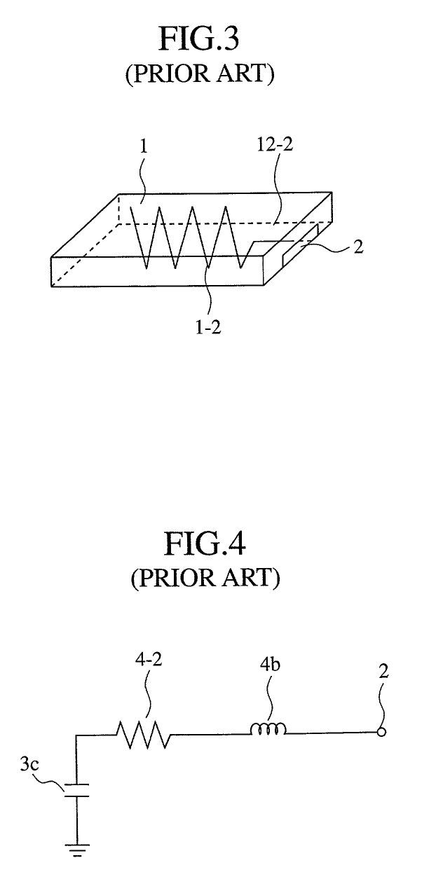

The antenna 1 includes a wire conductor formed on the surface of, or inside a rectangular parallelepiped dielectric block, which is operated as a radiation conductor. The antenna 1 is similar to that used in the conventional antenna apparatus shown in FIG. 1. A wavelength shortening effect is provided by a dielectric constant of the dielectric block, and the wire conductor is disposed on the surface of, or inside the dielectric block by being moved in a zigzag direction or helically wound. Accordingly, though compact, the antenna 1 has a characteristic similar to that of a wire antenna having a roughly 1/4 wavelength. FIG. 8 is Smith chart showing the locus of input impedance at a given frequency band when seen from the input terminal 2 of the antenna 1.

Now, the operation of the antenna device will be described briefly on the assumption that the impedance matching circuit 7 of the antenna apparatus of the first embodiment is designed to perform impedance matching at two frequencies f1 and f2 shown in FIG. 8. In this case, a relation between the frequencies f1 and f2 is represented by f1<f2. For convenience, matched impedance, i.e., the characteristic impedance of the external circuit 10 side, is set equal to the characteristic impedance Z0 of the transmission lines 6a and 6b.

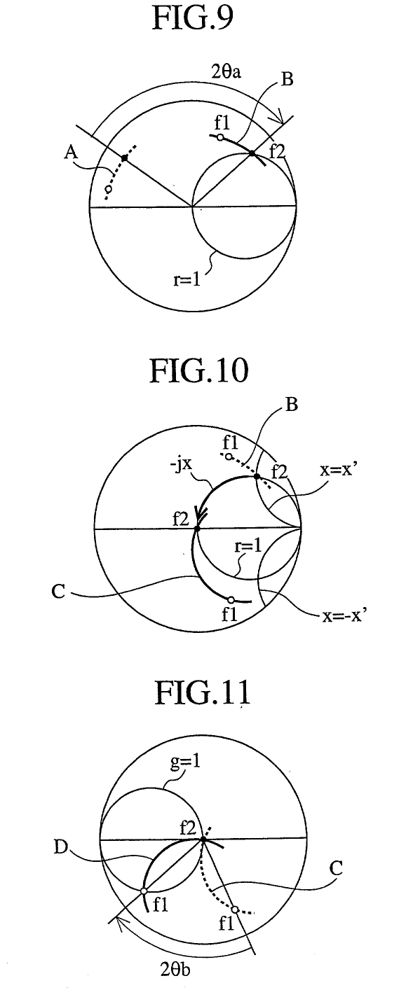

The locus of impedance shown in FIG. 8 is one when the antenna 1 side is seen from a node A (input terminal 2 of the antenna 1) on the circuit view of FIG. 7. An electrical length θa of the transmission line 6a connected to the node A has a value for rotating the locus clockwise until an impedance resistance component of the frequency f2 at a node B coincides with the characteristic impedance Z0. Thus, a locus when the antenna 1 side is seen from the node B is similar to that shown in Smith chart of FIG. 9.

With regard to the capacitance device 3a connected to the node B, at the frequency f2, one having a size equal to an impedance reactance component at the frequency f2 but with an opposite sign in FIG. 9 is used. In other words, one having a capacity value for providing minus reactance is used. Accordingly, a locus when the antenna 1 side is seen from a node C is one similar to that shown in Smith chart of FIG. 10. In this case, impedance at the frequency f2 coincides with the characteristic impedance Z0, thus achieving impedance matching. In this way, impedance matching at the frequency f2 has been completed by the first matching circuit 8-1 of FIG. 7.

Then, at the second matching circuit 8-2 connected to the node C, the locus of FIG. 10 is further rotated clockwise by the transmission line 6b. In this case, an electrical length θb of the transmission line 6b at the frequency f1 is selected such that conductance at the frequency f1 can be equal to 1/Z0, and susceptance can take a plus value. Accordingly, the locus of impedance at a node D is similar to that shown in Smith chart of FIG. 11. In this case, a susceptance value at the frequency f1 is set equal to a standardized value jb′. A reference code j denotes an imaginary unit.

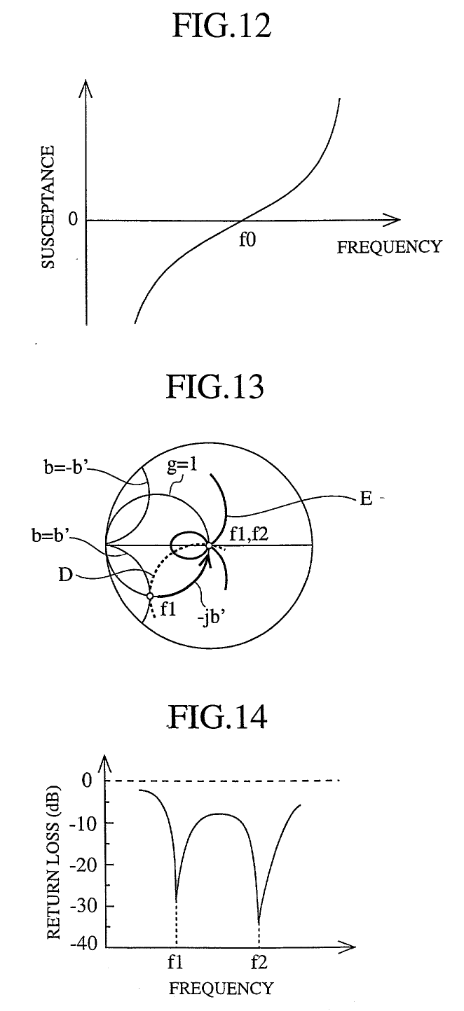

FIG. 12 shows the frequency characteristic of a suspeptance value for the parallel-resonant circuit. A frequency f0 shown in FIG. 12 is a resonance frequency. Generally, the parallel-resonant circuit exhibits a minus susceptance value at a frequency band lower than the resonance frequency f0, and a plus susceptance value at a frequency band higher than the resonance frequency f0. Thus, the parallel-resonant circuit 5 resonates at the frequency f2, and provides a minus susceptance value at the frequency f1 because of the relation f1<f2.

Accordingly, values are selected for the capacitance device 3b and the inductance device 4 constituting the parallel-resonant circuit 5 such that the parallel-resonant circuit 5 can resonate at the frequency f2, and exhibit a value of −jb′ at the frequency f1. For this reason, the locus of impedance at a node E (input terminal 9 of the antenna apparatus) is similar to that shown in FIG. 13, thus completing impedance matching at the frequency f1. At the frequency f2, the parallel-resonant circuit 5 is placed in a parallel-resonated state. Thus, the parallel-resonant circuit 5 is open, enabling the impedance matched state by the first matching circuit 8-1 to be maintained. As a result, the frequency characteristic of return losses of the antenna apparatus at the input terminal 9 is represented by a curve having troughs at the frequencies f1 and f2 shown in FIG. 14.

Device values of the inductance and capacitance devices 4 and 3b, and an electrical length θb of the transmission line 6b can be obtained based on simultaneous equations (1) and (2) described below as conditions for matching circuit designing. In the equations (1) and (2), line losses are ignored for simplicity of explanation.

1/(L·C)1/2 =2π·f2 (1)

Z0⁻¹·(Y1+jZ0⁻¹ tan θb)/(Z0⁻¹+jY1 tan θb)+j2πf1·C+(j2πf1·L)⁻¹=Z0⁻¹ (2)

Y1 in the equation (2) denotes admittance at the frequency f1 when the antenna 1 side is seen from the node C of FIG. 7, in other words, admittance at the frequency f1 in FIG. 10. L and C respectively denote the device values of the inductance and capacitance devices 4 and 3b. In this case, as it is a complex number equation, the equation (2) is divided into two equations between real and imaginary parts. The simultaneous equation has three expressions, and a solution to the equation can be found with L, C and θb set as unknown quantities.

Thus, according to the antenna apparatus of the first embodiment, since the impedance matching circuit 7 comprises the transmission lines 6a and 6b, the capacitance devices 3a and 3b and the inductance device 4 as chip devices, impedance matching can be carried out at two different frequencies even if the circuitry is very simple. In other words, the antenna apparatus of the first embodiment is advantageous in that the operation can be performed efficiently at the two frequency bands.

In addition, different from the case of the impedance matching device used in the conventional antenna apparatus, the impedance matching circuit 7 of the first embodiment is not constructed by using any active devices. Thus, the control circuit of the active device is made unnecessary. The antenna apparatus using the impedance matching circuit 7 can be constructed only by mounting the four chip components, i.e., the chip antenna 1, the chip capacitors 3a and 3b, and the chip inductor 4, on the dielectric substrate 12 having a coplanar conductor pattern formed thereon. Accordingly, the circuitry can be greatly simplified, making it possible to manufacture a compact and low-cost impedance matching circuit. The invention is also advantageous in that the presence of no active devices enables power consumption to be reduced, and that the simple circuitry enables the reliability of the antenna apparatus to be enhanced.

(Second Embodiment)

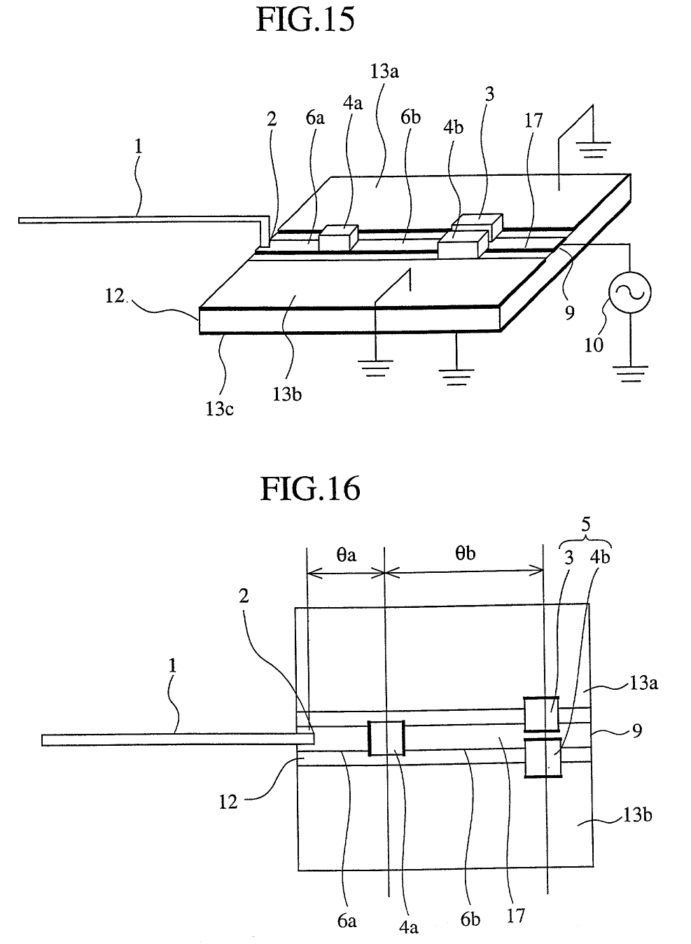

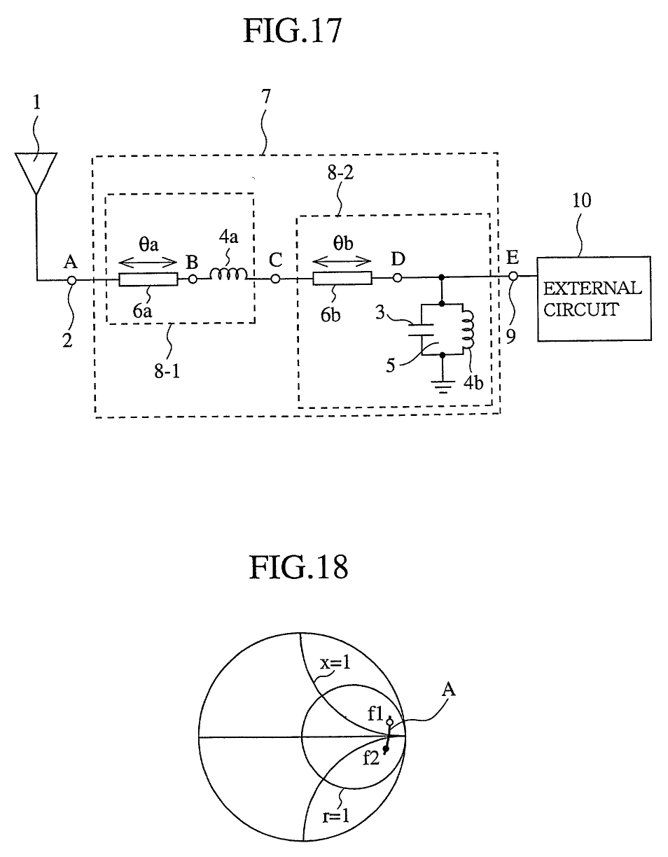

FIG. 15 is a perspective view showing an antenna apparatus according to the second embodiment of the invention; FIG. 16 an upper surface view of the antenna apparatus shown in FIG. 15; and FIG. 17 a circuit view of the antenna apparatus. The antenna apparatus shown in FIGS. 15 to 17 comprises, in combination, a wire antenna having a wavelength of roughly 1/2, used for a compact radio terminal such as a portable telephone set or the like, and an impedance matching circuit for operating the antenna at two frequency bands. The impedance matching circuit is constructed by mounting reactance devices as chip devices, such as capacitance and inductance devices, or the like, on a coplanar line.

In FIGS. 15 to 17, a reference numeral 1 denotes a wire antenna having a wavelength of roughly 1/2; 2 the input terminal of the antenna 1; 12 a dielectric substrate; 13a to 13c ground conductors provided in the surface and rear side of the dielectric substrate 12; 17 a coplanar line center conductor constituting a coplanar line as a power supply line for the antenna 1 with the dielectric substrate 12 and the ground conductors 13a to 13c; 10 an external circuit such as a power source circuit, an RF circuit or the like; and 9 the input terminal of the antenna apparatus, to which the external circuit 10 is connected. These portions are similar to those of the first embodiment shown in FIG. 5, and are denoted by like reference numerals.

A reference numeral 6a denotes a transmission line composed of the coplanar line, and having an electrical length θa at a frequency f2; 4a an inductance device such as a chip inductor, which is a circuit serially mounted on a gap formed in the coplanar line center conductor 17; 6b a transmission line composed of the coplanar line, and having an electrical length θb at a frequency f1; 3 a capacitance device such as a chip capacitor connected and mounted between the coplanar line center conductor 17 and the ground conductor 13a; and 4b an inductance device such as a chip inductor connected and mounted between the coplanar line center conductor 17 and the ground conductor 13b. The capacitance and inductance devices 3a and 4b are mounted on the same place of the coplanar line center conductor 17, constituting a parallel-resonant circuit 5.

A reference numeral 8-1 a first matching circuit including the transmission line 6a and the inductance device 4a, and provided for performing impedance matching for the antenna 1 at the frequency f2; 8-2 a second matching circuit including the transmission line 6b and the parallel-resonant circuit 5, and provided for performing impedance matching at the frequency f1; and 7 an impedance matching circuit including the first and second matching circuits 8-1 and 8-2, and adapted to perform impedance matching at the two frequencies f1 and f2.

Also, in the circuit views of FIG. 17, the nodes A to E of the circuit are shown for operation description made later.

In addition, device values of the capacitance and inductance devices 3 and 4b constituting the parallel-resonant circuit 5 are selected such that the parallel-resonant circuit 5 can resonate at the frequency f2, and exhibit a predetermined susceptance value at the frequency f1. In accordance with such selection, a required value is selected for the electrical length θb of the transmission line 6b.

Thus, the antenna apparatus of the second embodiment is different from the antenna apparatus of the first embodiment in that the antenna 1 is changed from the chip antenna to the wire antenna having a wavelength of roughly 1/2, and the chip device serially connected to the transmission line 6a in the first matching circuit 8 is changed from the chip capacitor 3a to the chip inductor 4a.

Next, description will be made about the operation of the antenna apparatus of the second embodiment constructed in the foregoing manner.

FIG. 18 is Smith chart showing the locus of input impedance at a given frequency band for the antenna 1 as the wire antenna having the wavelength of roughly 1/2. As it is the wire antenna having the wavelength of roughly 1/2, the antenna 1 has a high impedance characteristic as shown in FIG. 18. In this case, if the first matching circuit 81 including the transmission line 6a and the capacitance device 3a serially connected in combination is used as in the first embodiment, the setting of the resistance component of input impedance equal to the characteristic impedance Z0 and a reactance component to be positive at the frequency f2 results in a longer electrical length θa of the transmission line 6a. Consequently, with the inevitable enlargement of the first matching circuit 8-1, the impedance matching circuit 7 is increased in size, which is not preferable for constructing the circuit.

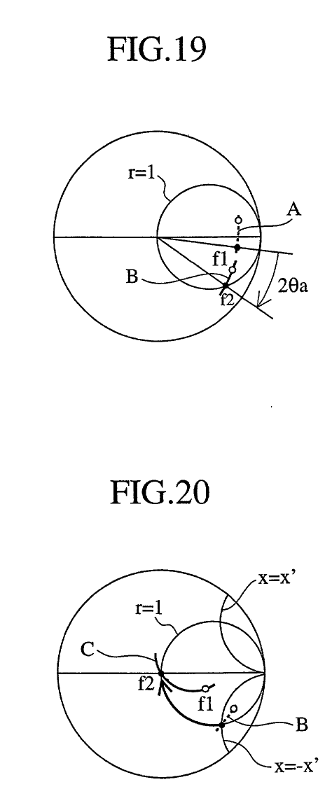

Therefore, in the antenna apparatus of the second embodiment, the first matching circuit 8-1 is made compact by using the combination of the transmission line 6a and the inductance device 4a serially connected therefor, and the impedance matching circuit 7 is thereby miniaturized. The transmission line 6a shown in FIG. 17 has an electrical length θa for rotating a locus clockwise until the reactance component of impedance is negative and the resistance component coincides with the characteristic impedance Z0 at the frequency f2 at a node B. Thus, a locus when the antenna 1 side is seen from the node B is similar to that shown in Smith chart of FIG. 19.

Then, for the inductance device 4a connected to the node B, one having an inductance value for providing the reactance of an absolute value equal to that of the reactance component of impedance at the frequency f2 in FIG. 19 is used. As a result, a locus when the antenna 1 side is seen from a node C is similar to that shown in Smith chart of FIG. 20. In this way, impedance matching has been completed at the frequency f2 by the first matching circuit 8-1 shown in FIG. 17.

The circuit operation of the external circuit 10 side is similar to that of the first embodiment described above with reference to FIGS. 11 to 14, and thus description thereof will be omitted.

The antenna apparatus of the second embodiment is advantageous in the same respect as that for the antenna apparatus of the first embodiment. The antenna apparatus of the second embodiment is further advantageous in that the circuit can be made compact when impedance matching is carried out for the antenna exhibiting the input impedance characteristic of high impedance.

(Third Embodiment)

The antenna apparatus of each of the first and second embodiments has been described based on the case that the first matching circuit 8-1 is constructed by serially connecting the transmission line 6a with the capacitance device 3a or the inductance device 4a. However, the impedance matching circuit 7 of the invention can be flexibly applied to impedance matching for various kinds of antennas 1 by changing the circuitry of the first matching circuit 8-1.

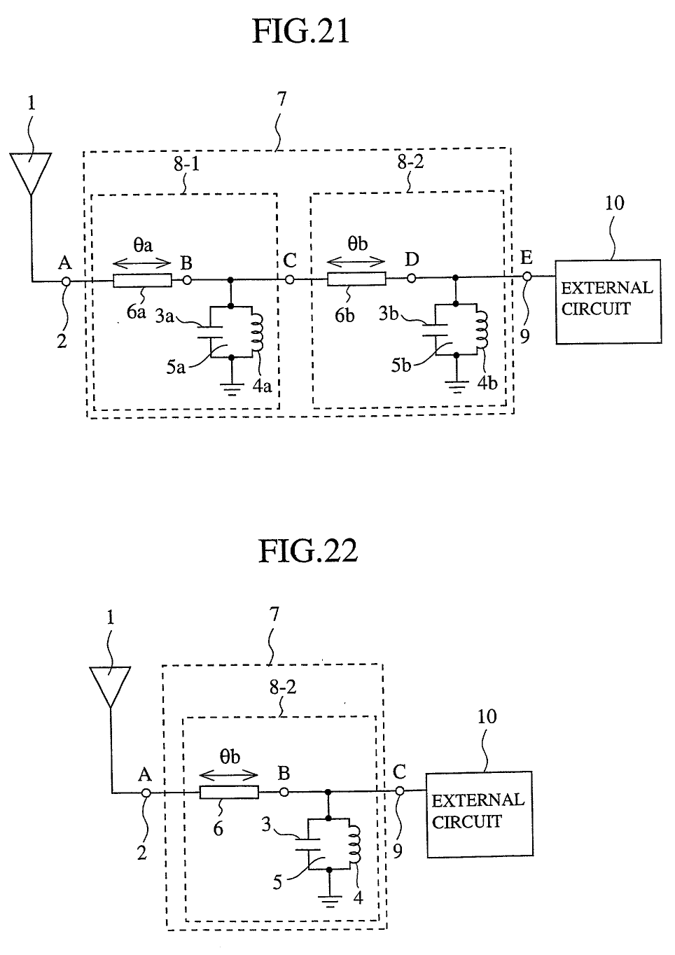

For example, as shown in FIG. 21, the first matching circuit 8-1 can be constructed by using the transmission line 6a, and a parallel-resonant circuit 5a including the capacitance device 3a and the inductance device 4a connected in parallel with the transmission line 6a. In the first matching circuit 8-1 shown in FIG. 21, device values are selected for the inductance and capacitance devices 4a and 3a such that the parallel-resonant circuit 5a of the first matching circuit 8-1 can resonate at the frequency f1, and exhibit required susceptance at the frequency f2. Accordingly, the parallel-resonant circuit 5a of the first matching circuit 8-1 is open at the frequency f1, while the parallel-resonant circuit 5b of the second matching circuit 8-2 is open at the frequency f2. Thus, the parallel-resonant circuits 5a and 5b can perform impedance matching at the two frequencies f1 and f2 without any interference with each other.

Apparently, the impedance matching circuit 7 used for the antenna apparatus of the third embodiment can be applied to the antennas 1 exhibiting various impedance characteristics by changing the circuitry of the first matching circuit 8-1, and is therefore advantageous in that impedance matching can be carried out at the two frequencies f1 and f2.

(Fourth Embodiment)

Each of the first to third embodiments has been described based on the case that the impedance matching circuit 7 comprises the first and second matching circuits 8-1 and 8-2. However, an impedance matching circuit 7 comprising only the second matching circuit 8-2 while omitting the first matching circuit 8-1 can be used. FIG. 22 is a circuit view showing the antenna apparatus of the fourth embodiment constructed in the above manner. As shown, the antenna apparatus uses the impedance matching circuit 7 composed of a transmission line 6, and only the second matching circuit 8-2. The second matching circuit 8-2 includes a parallel-resonant circuit 5 composed of capacitance and inductance devices 3 and 4.

The impedance matching circuit 7 having the circuitry constructed by omitting the first matching circuit 8-1 like that shown in FIG. 22 may be used in the following case. That is, assuming that an input impedance characteristic similar to that shown in Smith chart of FIG. 10 or FIG. 20 has already been obtained, in the antenna that has already been matched for impedance at a given frequency (frequency f2), impedance is to be matched also at the frequency f1 in addition to the frequency f2, at which impedance has been matched.

As described above, according to the fourth embodiment, since the use of the antenna 1 that has already been matched for impedance at the frequency f2 is assumed, the first matching circuit 8-1 can be omitted. Moreover, the impedance matching circuit 7 capable of performing impedance matching at the frequency f1 while maintaining the impedance matched state at the frequency f2 can be constructed by a simpler circuit.

(Fifth Embodiment)

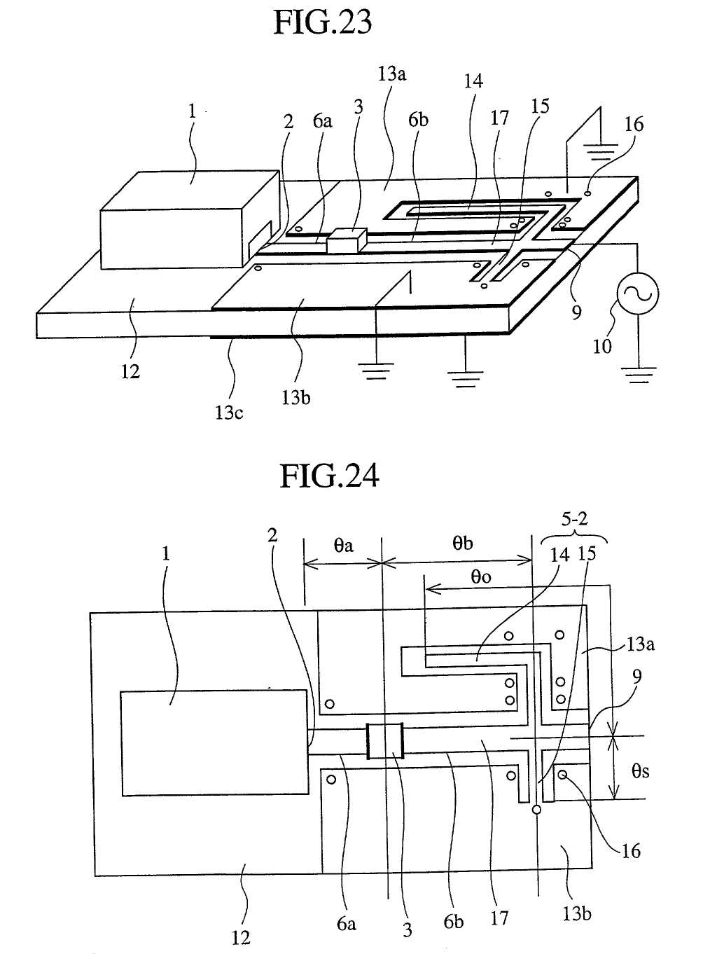

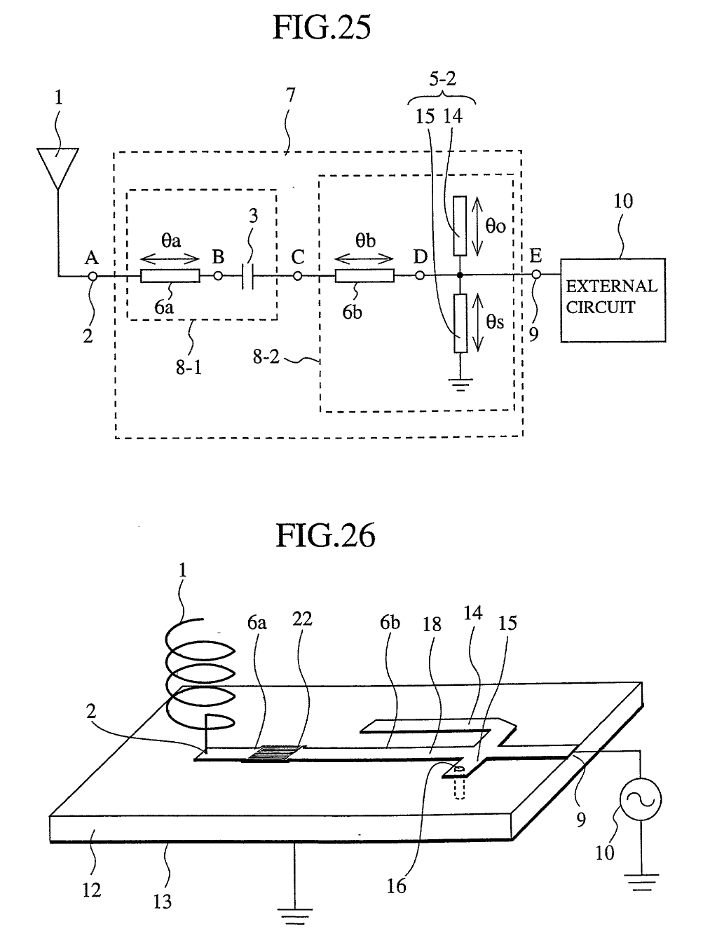

FIG. 23 is a perspective view showing an antenna apparatus according to the fifth embodiment of the invention; FIG. 24 an upper surface view of the antenna apparatus shown in FIG. 23; and FIG. 25 a circuit view of the antenna apparatus. The antenna apparatus shown in FIGS. 23 to 25 comprises, in combination, a commercially available chip antenna used for a compact radio terminal such as a portable telephone set or the like, and an impedance matching circuit for operating the antenna at two frequency bands. The impedance matching circuit is constructed by mounting a capacitance device such as a chip capacitor on a coplanar line as a planar transmission line.

In FIGS. 23 to 25, a reference numeral 1 denotes an antenna such as a chip antenna; 2 the input terminal of the antenna 1; 12 a dielectric substrate; 13a to 13c ground conductors provided in the surface and the rear side of the dielectric substrate 12; 17 a coplanar line center conductor constituting a coplanar line as a power supply line for the antenna 1 with the dielectric substrate 12 and the ground conductors 13a to 13c; 10 an external circuit such as a power source circuit, an RF circuit or the like; and 9 an input terminal, to which the external circuit 10 is connected. These portions are similar to those of the first embodiment shown in FIG. 5, and are denoted by like reference numerals.

A reference numeral 6a denotes a transmission line as a coplanar line, having an electrical length θa at the frequency f2; 3 a reactance device as a circuit serially provided on a gap formed in the coplanar line center conductor 17, in this case, a capacitance device such as a chip capacitor is used; 6b a transmission line as a coplanar line, having an electrical length θb at the frequency f1; 14 an open stub as a coplanar line, having an electrical length θo; and 15 a short stub as a coplanar line, having an electrical length θs. The open and short stubs 14 and 15 are connected to the same place of the coplanar line center conductor 17 oppositely to each other.

A reference numeral 5-2 denotes a 1/4 wavelength resonant circuit including the open and short stubs 14 and 15, and adapted to function as a parallel-resonant circuit. In this case, in the 1/4 wavelength resonant circuit 5-2, the distribution of the electrical lengths θo and θs is decided such that resonation can occur when a sum of the electrical lengths θo and θs of the open and short stubs 14 and 15 is nearly equal to π/2 at the frequency f2, i.e., substantially 1/4 of a wavelength at the frequency f2, and a predetermined susceptance value can be exhibited at the frequency f1. The sum of the electrical lengths θo and θs is normally set equal to an odd number multiple of nearly 1/4 of the wavelength at the frequency f2. In the described case, however, the sum is set nearly equal to 1/4 of the wavelength at the frequency f2 for the purpose of miniaturizing the circuit. In accordance with this setting, a required value is also selected for an electrical length θb of the transmission line 6b.

A reference numeral 8-1 denotes a first matching circuit including the transmission line 6a and the capacitance device 3, provided for performing impedance matching for the antenna 1 at the frequency f2; 8-2 a second matching circuit including the transmission line 6b, and the 1/4 wavelength resonant circuit 5-2 having the open and short stubs 14 and 15, provided for performing impedance matching at the frequency f1; and 7 an impedance matching circuit including the first and second matching circuits 8-1 and 8-2, provided for performing impedance matching at the two frequencies f1 and f2.

A reference numeral 16 denotes a through-hole for electrically connecting the ground conductors 13a and 13b provided in the surface of the dielectric substrate 12 with the ground conductor 13c provided in the rear side thereof, and suppressing the propagation of an unnecessary mode.

In the circuit view of FIG. 25, the nodes A to E of the circuit are shown for later operation description.

Now, the operation of the antenna apparatus will be described.

The operation of the antenna apparatus of the fifth embodiment constructed in the foregoing manner is substantially similar to that of the antenna apparatus of the first embodiment. Specifically, in the antenna apparatus of the first embodiment, the resonant circuit inside the impedance matching circuit 7 is the parallel-resonant circuit composed of the chip device. In the antenna apparatus of the fifth embodiment, this circuit is changed to the 1/4 wavelength resonant circuit 5-2 composed of the short and open stubs 15 and 14. As these short and open stubs 15 and 14 are connected in parallel with the transmission line 6b, the 1/4 wavelength resonant circuit 5-2 also functions as a parallel-resonant circuit.

Accordingly, the operation principle of the antenna apparatus is substantially identical to that of the antenna apparatus of the first embodiment. Thus, if the impedance locus of the antenna 1 provided is similar to that shown in Smith chart of FIG. 8, then the loci of impedance when the antenna 1 side is seen from the nodes B to E are respectively similar to those shown in Smith charts of FIGS. 9 to 11, and 13.

Electrical lengths θo, θs and θb of the open and short stubs 14a and 15 and the transmission line 6b can be respectively obtained by solving the following conditional expressions (3) and (4) as simultaneous equations:

θs+θo=π/2 (3)

Z0⁻¹·(Y1+jZ0⁻¹ tan θb(/(Z0⁻¹+jY1 tan θb)+jZ0s⁻¹ tan(f1·f2⁻¹·θo)−jZ0s⁻¹ cot(f1·f2⁻¹·θs)=Z0⁻¹ (4)

Y1 in the equation (4) represents admittance at the frequency f1 when the antenna 1 side is seen from the node C of FIG. 25, which corresponds to the admittance at the frequency f1 in Smith chart of FIG. 10. Z0s represents characteristic impedance for the open and short stubs 14 and 15. As it is a complex number equation, the equation (4) is divided into two equations between real and imaginary parts. Accordingly, the simultaneous equation has three expressions, and a solution can be found with the three electrical lengths θs, θo and θb set as unknown quantities.

In the foregoing, in the first matching circuit 8-1, the capacitance device 3 was used as the reactance device serially connected to the transmission line 6a. Needless to say, however, an inductance device may be used for the reactance device, which is serially connected to the transmission line 6a.

Apparently, the antenna apparatus of the fifth embodiment has features similar to those of the antenna apparatus of the first embodiment, and thus providing a similar advantage. Moreover, the antenna apparatus of the fifth embodiment is advantageous in that since the resonant circuit of the impedance matching circuit 7 is constructed by using the stubs, not any chip devices, the number of chip devices can be reduced to facilitate manufacturing and lower manufacturing costs.

Needless to say, the antenna apparatus of the fifth embodiment is similar to that of the first embodiment in that by changing the circuitry of the first matching circuit 8-1, impedance matching can be performed flexibly for various kinds of antennas 1.

(Sixth Embodiment)

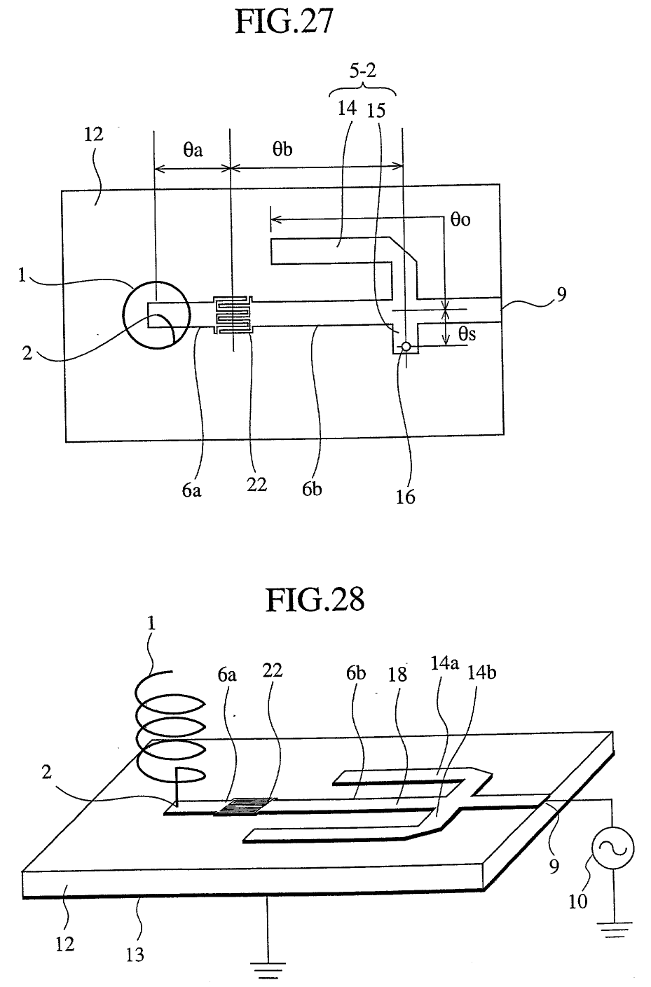

FIG. 26 is a perspective view showing an antenna apparatus of the sixth embodiment of the invention; and FIG. 27 an upper surface view of the antenna apparatus shown in FIG. 26. The antenna apparatus shown in FIGS. 26 and 27 comprises, in combination, a compact helical antenna used for a compact radio terminal such as a portable telephone set or the like, and an impedance matching circuit for operating the antenna at two frequency bands. The impedance matching circuit is constructed by using a micro strip line as a planar transmission line.

In FIGS. 26 and 27, a reference numeral 1 denotes an antenna, which is a compact helical antenna; 2 the input terminal of the antenna 1; 12 a dielectric substrate; 13 a ground conductor provided in the rear of the dielectric substrate 12; 18 a strip conductor constituting a micro strip line as a power supply line for the antenna 1 with the dielectric substrate 12 and the ground conductor 13; 10 an external circuit such as a power source circuit, an RF circuit or the like; and 9 an input terminal, to which the external circuit 10 is connected.

A reference numeral 6a denotes a transmission line as a micro strip line, having an electrical length θa at the frequency f2; 6b a transmission line as a micro strip line, having an electrical length θb at the frequency f1; 22 an interdigital capacitor as a capacitance device having a conductor pattern, interposed between the transmission lines 6a and 6b to apply serial capacitance; 14 an open stub as a micro strip line, having an electrical length θo; 15 a short stub as a micro strip line, having an electrical length θs; and 16 a through-hole for connecting the tip of the short stub 15 to the ground conductor 13. The open and short stubs 14 and 15 are connected to the same place of the strip conductor 18 oppositely to each other.

A reference numeral 5-2 denotes a 1/4 wavelength resonant circuit including the open and short stubs 14 and 15, and adapted to function as a parallel-resonant circuit. In this case, in the 1/4 wavelength resonant circuit 5-2, the distribution of the electrical lengths θo and θs is decided such that resonance can occur when a sum of the electrical lengths θo and θs of the open and short stubs 14 and 15 is nearly equal to a π/2 at the frequency f2, i.e., substantially 1/4 of a wavelength at the frequency f2, and a predetermined susceptance value can be exhibited at the frequency f1. The sum of the electrical lengths θo and θs is normally set equal to an odd number multiple of nearly 1/4 of the wavelength at the frequency f2. In the described case, however, the sum is set equal to nearly 1/4 of the wavelength at the frequency f2 for the purpose of miniaturization. In accordance with this setting, a required value is also selected for the electrical length θb of the transmission line 6b.

Accordingly, the circuit view of the antenna apparatus of the sixth embodiment is similar to that of the antenna apparatus of the fifth embodiment shown in FIG. 25. However, in the antenna apparatus of the sixth embodiment, the first matching circuit 8-1 includes the transmission line 6a, and the interdigital capacitor 22. The second matching circuit 8-2 includes the transmission line 6b, and the 1/4 wavelength resonant circuit 5-2 including the open and short stubs 14 and 15 constituting the micro strip line.

In the antenna apparatus constructed in the foregoing manner, when a small helical diameter of the antenna 1 is selected with respect to a wavelength, and a helical conductor is wound at small pitches, the antenna 1 exhibits an impedance characteristic substantially similar to that shown in Smith chart of FIG. 8. Thus, the operation of the antenna apparatus of the sixth embodiment is also similar to that of the antenna apparatus of the first or fifth embodiment, providing a similar advantage. Also, in this case, the electrical lengths θo, θs and θb of the open and short stubs 14 and 15, and the transmission line 6b can be obtained based on the equations (3) and (4) described above with reference to the fifth embodiment.

In the foregoing, the first matching circuit 8-1 included the transmission line 6a having the electrical length θa, and the interdigital capacitor 22. However, the interdigial capacitor 22 may be changed to the 1/4 wavelength resonant circuit including open and short stubs. In this case, the electrical lengths of the short and open stubs may be set such that a sum of the electrical lengths of the short and open stubs of the 1/4 wavelength resonant circuit can be set equal to roughly 1/4, or an odd number multiple, of a wavelength at the frequency f1, and a sum of the susceptance values of the short and open stubs can take a predetermined susceptance value at the frequency f2.

In addition, in the foregoing, the first matching circuit 8-1 was interposed between the input terminal 2 of the antenna 1 and the second matching circuit 8-2. However, as described above with reference to the fourth embodiment, the first matching circuit 8-1 may be omitted.

Thus, the antenna apparatus of the sixth embodiment has features similar to those of the antenna apparatus of the first embodiment, providing a similar advantage. In addition, in the antenna apparatus of the sixth embodiment, the parallel-resonant circuit 5-2 is constructed by using the open and short stubs 14 and 15 constituting the micro strip line, but not any chip devices, and the interdigital capacitor 22 is used for the capacitance device of the first matching circuit 8-1. Accordingly, no chip devices are present, and the antenna apparatus can be manufactured only by forming the pattern of the strip conductor 18 on the dielectric substrate 12. Therefore, low-cost manufacturing can be facilitated. Moreover, since the capacitor device having a given capacitance value can be manufactured accurately and easily, an impedance matching circuit with improved performance characteristics is provided.

(Seventh Embodiment)

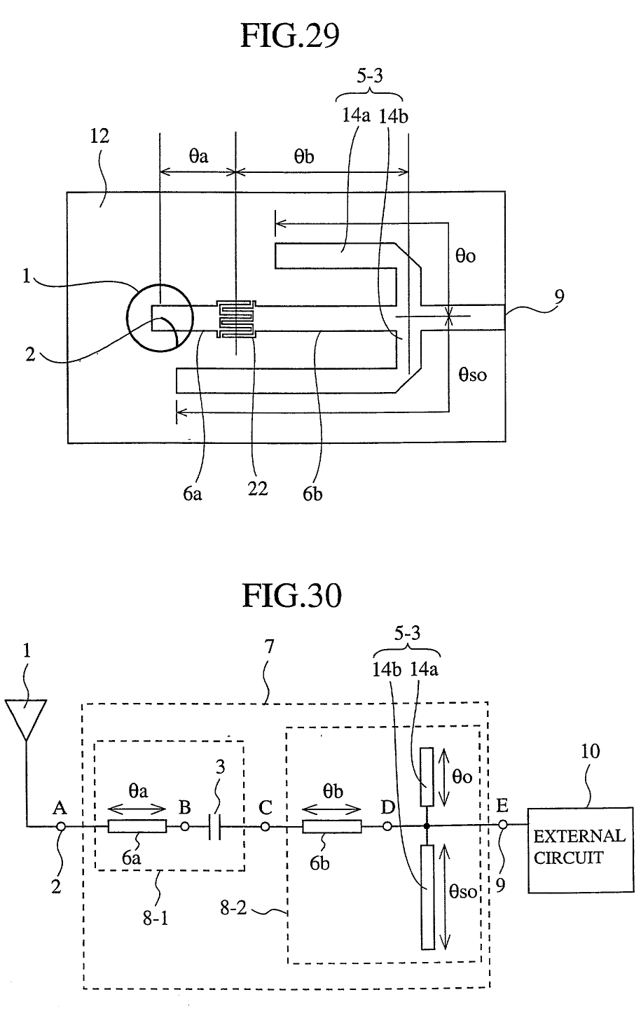

FIG. 28 is a perspective view showing an antenna according to the seventh embodiment of the invention; FIG. 29 an upper surface view of the antenna apparatus shown in FIG. 28; and FIG. 30 a circuit view of the antenna apparatus. The antenna apparatus shown in FIGS. 28 to 30 comprises, in combination, a compact helical antenna used for a compact radio terminal such as a portable telephone set or the like, and an impedance matching circuit for operating the antenna at two frequency bands. The impedance matching circuit is constructed by using a micro strip line as a planar transmission line.

In FIGS. 28 to 30, a reference numeral 1 denotes an antenna, which is a compact helical antenna; 2 the input terminal of the antenna 1; 12 a dielectric substrate; 13 a ground conductor provided in the rear side of the dielectric substrate 12; 18 a strip conductor constituting a micro strip line as a power supply line for the antenna 1 with the dielectric substance 12 and the ground conductor 13; 10 an external circuit such as a power source circuit, an RF circuit or the like; and 9 an input terminal, to which the external circuit 10 is connected. These portions are similar to those of the sixth embodiment shown in FIG. 26, and are denoted by like reference numerals.

A reference numeral 6a denotes a transmission line as a micro strip line, having an electrical length θa at the frequency f2; 6b a transmission line as a micro strip line, having an electrical length θb at the frequency f1; 22 an interdigital capacitor as a capacitance device having a conductor pattern, interposed between the transmission lines 6a and 6b to apply serial capacitance; 14a a first open stub as a micro strip line, having an electrical length θo; and 14b a second open stub as a micro strip line, having an electrical length θso. The first and second open stubs 14a and 14b are connected to the same place of the strip conductor 18 oppositely to each other.

A reference numeral 5-3 denotes a 1/2 wavelength resonant circuit composed of the first and second open stubs 14a and 14b, and adapted to function as a parallel-resonant circuit. In this case, in the 1/2 wavelength resonant circuit 5-3, the distribution of the electrical lengths θo and θso is decided such that resonance can occur when a sum of the electrical lengths θo and θso of the first and second open stubs 14a and 14b is nearly equal to π at the frequency f2, i.e., nearly equal to 1/2 of a wavelength at the frequency f2, and a predetermined susceptance value can be exhibited at the frequency f1. The sum of the electrical lengths θo and θso is normally set equal to an integral multiple of nearly 1/2 of the wavelength at the frequency f2. In the described case, however, the sum is set nearly equal to 1/2 of the wavelength at the frequency f2 for the purpose of miniaturizing the circuit. In accordance with this setting, a required value is also selected for the electrical length θb of the transmission line 6b.

A reference numeral 8-1 denotes a first matching circuit including the transmission line 6a and the capacitance device 3 as the interdigital capacitor 22, and adapted to perform impedance matching for the antenna 1 at the frequency f2; 8-2 a second matching circuit including the transmission line 6b, and the 1/2 wavelength resonant circuit 5-3 having the first and second open stubs 14a and 14b constituting the micro strip line, and adapted to perform impedance matching at the frequency f1; and 7 an impedance matching circuit including the first and second matching circuits 8-1 and 8-2, and provided for performing impedance matching at the two frequencies f1 and f2.

In the circuit view of FIG. 30, the nodes A to E of the circuit are also shown for later operation description.

Next, the operation of the antenna apparatus will be described.

The operation of the antenna apparatus of the seventh embodiment is substantially similar to that of the antenna apparatus of the sixth embodiment, providing a similar advantage. In the sixth embodiment, the parallel-resonant circuit inside the second matching circuit 8-2 is the 1/4 wavelength resonant circuit 5-2 including the short and open stubs in combination. As shown in FIG. 30, however, in the antenna apparatus of the seventh embodiment, the parallel-resonant circuit is the 1/2 wavelength resonant circuit 5-3 including the two open stubs 14a and 14b in combination. As these two stubs are connected to the same place of the transmission line 6b in parallel, the 1/2 wavelength resonant circuit 5-3 can also be regarded as a kind of a parallel-resonant circuit.

Accordingly, the operation principle of the antenna apparatus of the seventh embodiment is substantially similar to that for the antenna apparatus of the sixth embodiment. For this reason, if the impedance locus of the antenna 1 provided is similar to that shown in Smith chart of FIG. 8, then the loci of impedance when the antenna 1 side is seen from the nodes B to E of FIG. 30 are similar to those shown in Smith charts of FIGS. 9 to 11, and 13.

The electrical lengths θo, θso and θb of the first and second open stubs 14a and 14b and the transmission line 6b can be obtained by solving the following conditional expressions (5) and (6) as simultaneous equations:

θso+θo=π (5)

Z0⁻¹·(Y1+jZ0⁻¹ tan θb)/(Z0⁻¹+jY1 tan θb)+jZ0s⁻¹ tan(f1·f2⁻¹·θo)+jZ0s⁻¹ tan(f1·f2⁻¹·so)=Z0⁻¹ (6)

Y1 in the equation (6) represents admittance at the frequency f1 when the antenna 1 side is seen from the node C, which corresponds to the admittance at the frequency f1 in FIG. 10. Z0s represents characteristic impedance for each of the open stubs 14a and 14b. As it is a complex number equation, the equation (6) is divided into two equations between real and imaginary parts. Thus, the simultaneous equation has three expressions, and a solution can be found with the three electrical lengths θso, θo and θb set as unknown quantities.

In the foregoing, the first matching circuit 8-1 included the transmission line 6a having the electrical length θa, and the interdigital capacitor 22. However, the interdigital capacitor 22 may be changed to the 1/2 wavelength resonant circuit including the first and second open stubs. In this case, the electrical lengths of the first and second open stubs may be set such that a sum of the electrical lengths of the first and second open stubs can be set equal to roughly 1/2, or an integral multiple, of a wavelength at the frequency f1, and a sum of susceptance values of the two open stubs can take a predetermined susceptance value at the frequency f2.

In addition, in the foregoing, the first matching circuit 8-1 was interposed between the input terminal 2 of the antenna 1 and the second matching circuit 8-2. However, as described above with reference to the fourth embodiment, the first matching circuit 8-1 may be omitted.

Apparently, the antenna apparatus of the seventh embodiment has features similar to those of the antenna apparatus of the sixth embodiment, providing a similar advantage. Moreover, in the antenna apparatus of the seventh embodiment, the two stubs used are open stubs, and no short stubs are used. Accordingly, a through-hole is made unnecessary, making it possible to facilitate low-cost manufacturing.

(Eighth Embodiment)

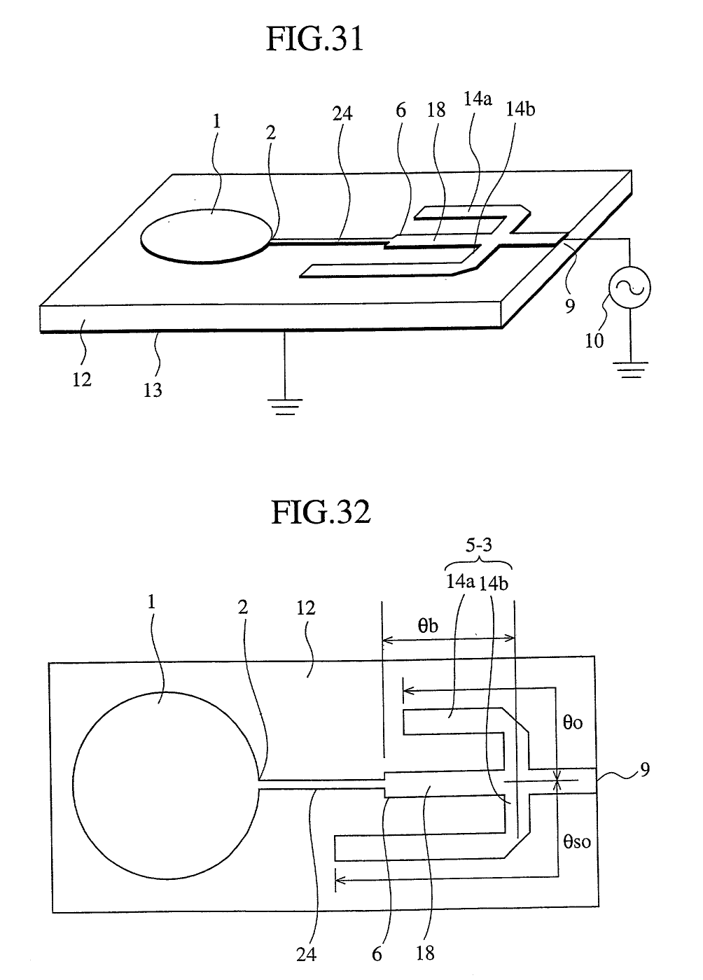

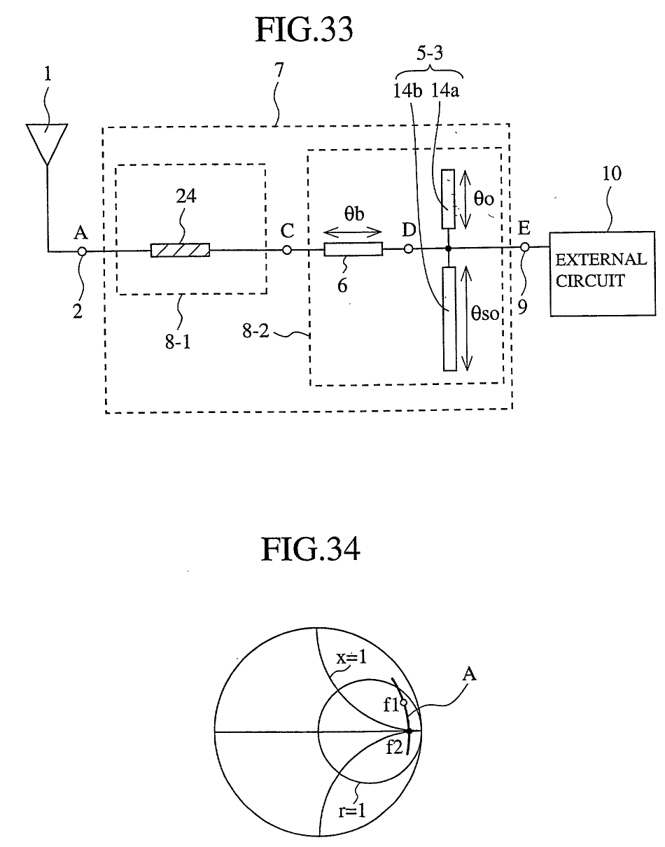

FIG. 31 is a perspective view showing an antenna apparatus according to the eighth embodiment of the invention; FIG. 32 an upper surface view of the antenna apparatus shown in FIG. 31; and FIG. 33 a circuit view of the antenna apparatus. The antenna apparatus shown in FIGS. 31 to 33 comprises, in combination, a circular micro strip antenna, and an impedance matching circuit for operating the antenna at two frequency bands. The impedance matching circuit is constructed by using a micro strip line.

In FIGS. 31 to 33, a reference numeral 1 denotes an antenna, which is a circular micro strip antenna; 2 the input terminal of the antenna 1; 12 a dielectric substrate, the antenna 1 being provided in the surface of this dielectric substrate 12; 13 a ground conductor provided in the rear of the dielectric substrate 12; 18 a strip conductor constituting a micro strip line as a power supply line for the antenna 1 with the dielectric substrate 12 and the ground conductor 13, and also constituting the antenna 1; 10 an external circuit such as a power source circuit, an RF circuit or the like; and 9 an input terminal, to which the external circuit 10 is connected.

A reference numeral 24 denotes a 1/4 wavelength impedance transformer at the frequency f2, constructed by a micro strip line; 6 a transmission line as a micro strip line, having an electrical length θb at the frequency f1; 14a a first open stub as a micro strip line, having an electrical length θo; and 14b a second open stub as a micro strip line, having an electrical length θso. These two open stubs 14a and 14b are connected to the same place of the strip conductor 18 oppositely to each other.

A reference numeral 5-3 denotes a 1/2 wavelength resonant circuit including the first and second open stubs 14a and 14b. In this case, in the 1/2 wavelength resonant circuit 5-3, the distribution of the electrical lengths θo and θso is decided such that resonance can occur when a sum of the electrical lengths θo and θso of the open stubs 14a and 14b is nearly equal to X at the frequency f2, i.e., nearly equal to 1/2 of a wavelength at the frequency f2, and a predetermined susceptance value can be exhibited at the frequency f1. Th sum of the electrical lengths θo and θso is normally set equal to an integral multiple of nearly 1/2 of the wavelength at the frequency f2. In the described case, however, the sum is set nearly equal to 1/2 of the wavelength at the frequency f2 for the purpose of miniaturizing the circuit. In accordance with this setting, a required value is also selected for the electrical length θb of the transmission line 6b.

A reference numeral 8-1 denotes a first matching circuit including a 1/4 wavelength impedance transformer 24 constructed by a micro strip line, and adapted to perform impedance matching for the antenna 1 at the frequency f2; 8-2 a second matching circuit including the transmission line 6, and the 1/2 wavelength resonant circuit 5-3 including the first and second open stubs 14a and 14b formed by a micro strip line, and adapted to perform impedance matching at the frequency f1; and 7 an impedance matching circuit including the first and second matching circuits 8-1 and 8-2, and provided for performing impedance matching at the two frequency bands.

In the circuit view of FIG. 33, the nodes A to E of the circuit are also shown for later operation description.

Next, the operation of the antenna apparatus will be described.

FIG. 34 is Smith chart showing the input impedance characteristic of the antenna 1, which is a circular micro strip antenna. The characteristic shown in FIG. 34 is equivalent to that when the antenna 1 side is seen from the node A, shown in the circuit view of FIG. 33. Generally, in such a circular micro trip antenna, when the micro strip line is connected to the input terminal 2 of the antenna 1 to supply power as shown, the characteristic of high impedance like that shown in FIG. 34 is exhibited. It is assumed that the impedance characteristic shown in FIG. 34 is one obtained as a result of adjusting the pattern size of the antenna 1 in such a way as to set a reactance component equal to 0 at the frequency f2 as one of frequencies for the operation of impedance matching.

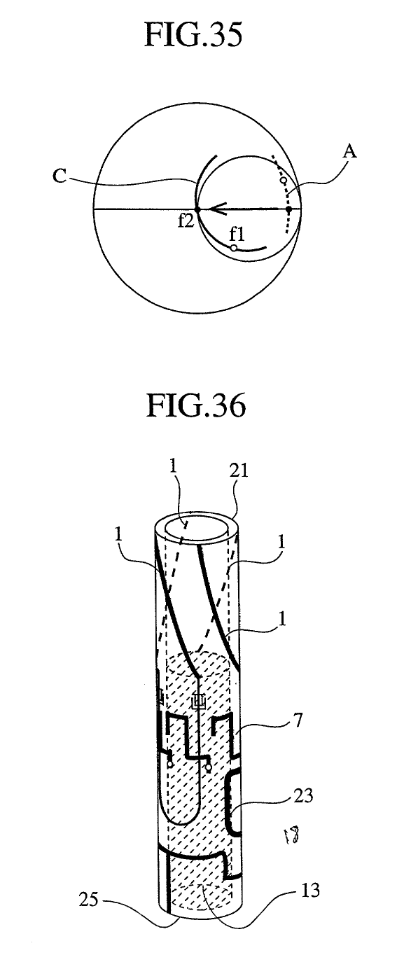

Thus, the connection of the 1/4 wavelength impedance transformer 24 to the antenna 1 brings about a characteristic like that shown in Smith chart of FIG. 35, and a resistance component at the frequency f2 of FIG. 34 is transformed into characteristic impedance Z0 (standardized impedance or characteristic impedance of the external circuit 10). For the characteristic shown in FIG. 35, the operation of impedance matching performed at the frequency f1 while maintaining the impedance matched state at the frequency f2 is similar to that of the sixth embodiment.

Apparently, the antenna apparatus of the eight embodiment has features similar to those of the antenna apparatus of the seventh embodiment, providing a similar advantage. Moreover, in the antenna apparatus of the eighth embodiment, the 1/4 wavelength impedance transformer 24 is used for the first matching circuit 8-1 by taking into consideration the characteristic of the circular micro strip antenna. Accordingly, the circuitry is simple, making it possible to perform low-cost manufacturing.

(Ninth Embodiment)

FIG. 36 is a perspective view showing an antenna apparatus according to the ninth embodiment of the invention. The antenna apparatus of the ninth embodiment comprises, in combination: an antenna, which is a 4-wire (N-wire) helical antenna including 4 (N) helical radiation devices formed on a hollow cylindrical dielectric; 4 (N impedance matching circuits respectively connected to the 4 helical radiation devices, and provided for operating the radiation devices at two frequency bands; and 4 d-distributing circuits (N distributing circuits) respectively connected to the 4 impedance matching circuits, and provided for distributing or synthesizing microwaves while providing a predetermined phase difference among the impedance matching circuits. A power supply circuit is provided integrally with the antenna. This antenna apparatus is used for a compact radio terminal such as a portable telephone set or the like. For each of the impedance matching circuits, the one constructed by using the micro strip line, described above with reference to the sixth embodiment, is used.

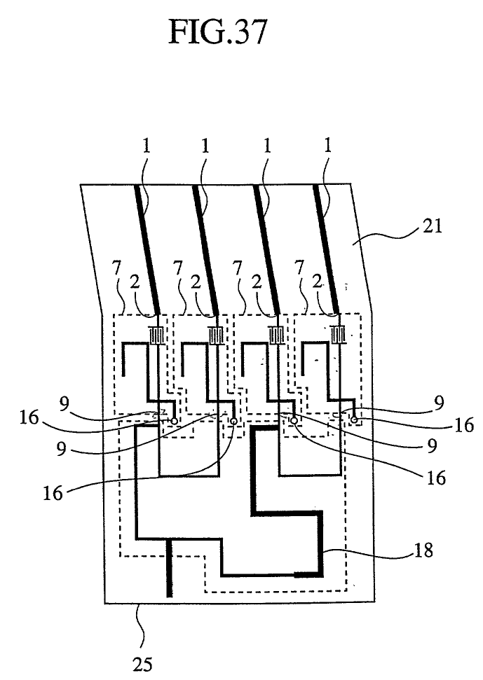

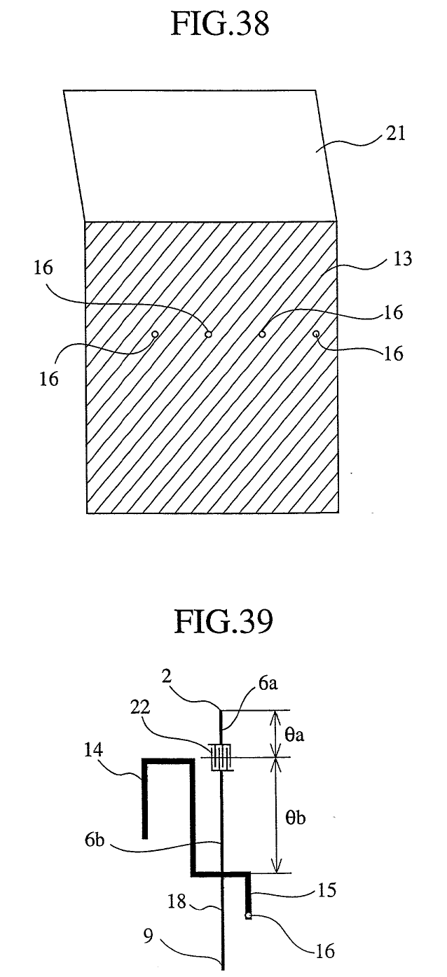

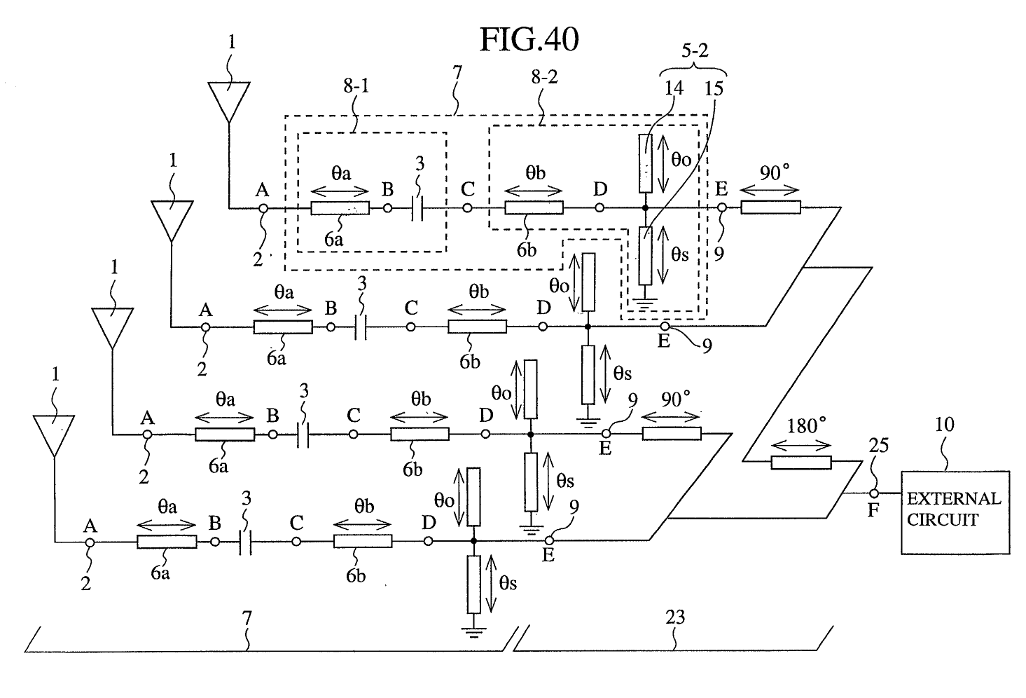

FIG. 37 is a development showing the cylindrical outer surface of the antenna apparatus shown in FIG. 36; FIG. 38 also a development showing the cylindrical inner surface of the same; FIG. 39 an expanded view showing a strip conductor pattern in the impedance matching circuit portion of the antenna apparatus; and FIG. 40 a circuit view of the antenna apparatus shown in FIG. 36.

In FIGS. 36 to 40, a reference numeral 21 denotes a hollow cylindrical dielectric; 1 an antenna including 4 helical radiation devices, formed in a strip conductor pattern on the outer surface of the cylindrical dielectric 21; 2 the input terminal of each of the 4 helical radiation devices of the antenna 1; and 13 a ground conductor provided in a region, which is a part of the inner surface of the cylindrical dielectric 21. The ground conductor 13 is not provided in a region having the 4 helical radiation devices of the antenna 1 formed on the outer surface. A reference numeral 18 denotes a strip conductor constituting a micro strip line with the cylindrical dielectric 21 and the ground conductor 13.

A reference numeral 6a denotes a transmission line as a micro strip line, having an electrical length θa at the frequency f2; and 22 an interdigital capacitor serially connected to the transmission line 6a. This interdigital capacitor 22 is shown as a capacitance device 3 in the circuit-view of FIG. 40. A reference numeral 6b denotes a transmission line as a micro strip line, having an electrical length θb at the frequency f1; 14 an open stub as a micro strip line, having an electrical length θo; 15 a short stub as a micro strip line, having an electrical length θs; and 16 a through-hole provided in the tip of the short stub 15 for connecting the strip conductor 18 to the ground conductor 13 provided in the inner surface of the cylindrical dielectric 21. The open and short stubs 14 and 15 are connected to the same place of the strip conductor 18 oppositely to each other.

A reference numeral 5-2 denotes a 1/4 wavelength resonant circuit including the open and short stubs 14 and 15, and adapted to function as a parallel-resonant circuit. In this case, the distribution of the electrical lengths θo and θs is decided such that parallel resonance can occur when a sump of the electrical lengths θo and θs of the open and short stubs is nearly equal to π/2 at the frequency f2 (nearly equal to 1/4 of a wavelength at the frequency f2), and a predetermined susceptance value can be exhibited at the frequency f1. The sum of the electrical lengths θo and θs is normally set equal to 1/4, or an odd number multiple, of the wavelength at the frequency f2. In the described case, however, the sum is set nearly equal to 1/4 of the wavelength at the frequency f2 for the purpose of miniaturization. In accordance with this setting, a predetermined value is also selected for the electrical length θb of the transmission line 6b.

A reference numeral 8-1 denotes a first matching circuit including the transmission line 6a and the capacitor device 3 as the interdigital capacitor 22, and adapted to perform impedance matching for the antenna 1 at the frequency f2: 8-2 a second matching circuit including the transmission line 6b, and the 1/4 wavelength resonant circuit 5-2 having the open and short stubs 15 constituting the micro strip line, and adapted to perform impedance matching at the frequency f1; and 7 an impedance matching circuit including the first and second matching circuits 81 and 8-2, and provided for performing impedance matching at the two frequencies f1 and f2. The prepared number of such impedance matching circuits 7 coincides to 4 in a corresponding relation to the helical radiation devices of the antenna 1. A reference numeral 9 denotes the input terminal of each of the impedance matching circuits 7. Thus, each impedance matching circuit 7 is similar in configuration to the impedance matching circuit of the sixth embodiment.

A reference numeral 23 denotes each of 4-distribution circuit including a micro strip line constructed by including the cylindrical dielectric 21, the ground conductor 13 and the strip conductor 18, and having 4 (N) distributing terminals respectively exhibiting required distribution amplitude and phase characteristics, each of the distributing terminals being connected to the input terminal 9 of each of the 4 impedance matching circuits. The 4-distribution circuit 23 is adapted to generate a phase difference of about 90° among the 4 terminals. A reference numeral 25 denotes the input terminal of the 4-distribution circuit 23, which is the input terminal of the antenna apparatus.

The ground conductor 13 is provided in the region of the inner surface of the cylindrical dielectric, which corresponds to a region having the strip conductor of the micro strip line constructing the impedance matching circuits 7 and the 4-distribution circuit 23 present on the outer surface thereof. A reference numeral 10 denotes an external circuit such as a power source circuit, an RF circuit or the like, connected to the input terminal 25 of the antenna apparatus constructed in the above manner.

In the circuit view of FIG. 40, the nodes A to F of the circuit are also shown for later operation description.

Next, the operation of the antenna apparatus will be described.

The antenna 1 used for the antenna apparatus of the ninth embodiment shown in FIGS. 36 to 40 performs circularly polarized wave radiation by using the 4-distribution circuit to generate a phase difference of 90°, and supplying power among the 4 helical radiation devices. The radiation directivity of such a 4-wire helical antenna 1 is broad around the axial direction of the cylindrical dielectric 21, and frequently used for a satellite portable terminal or the like because of its broad coverage. The antenna apparatus of the ninth embodiment enables such a 4-wire helical antenna 1 to be used at the two frequency bands.

Specifically, since the 4 helical radiation devices of the antenna 1 are interconnected to operate in an integrated manner, active impedance when the antenna 1 side is seen from the input terminal 2 of each of the 4 helical radiation devices can be regarded as load impedance to be matched. Accordingly, the impedance matching circuit 7 is designed based on the active impedance when the antenna 1 side is seen from the input terminal 2 of each helical radiation device of the antenna 1. In the described case, the locus of active impedance when the antenna 1 side is seen from the input terminal 2 (node A) of the helical radiation device is similar to that shown in Smith chart of FIG. 8. Thus, the operation of the impedance matching circuit 7 is substantially similar to that of the antenna apparatus of each of the first, fifth and sixth embodiments.

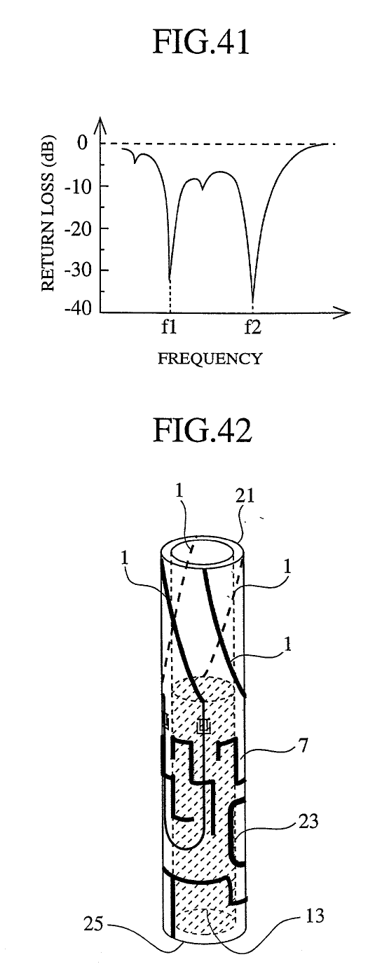

Therefore, the loci of impedance when the antenna 1 side is seen from the nodes B to E of FIG. 40 are similar to those shown in Smith chars of FIGS. 9 to 11, and 13. In this case, at the node E, impedance has already been matched at the two frequencies f1 and f2. Accordingly, even in a characteristic when the antenna 1 side is seen from the node F, the impedance matched states at the two frequencies f1 and f2 are maintained. As a result, as shown in FIG. 41, a reflection characteristic at the node F can be represented by a curve having return loss troughs at the frequencies f1 and f2. In FIG. 41, an ordinate indicates a return loss, and an abscissa indicates a frequency.

As described above, in the antenna apparatus of the ninth embodiment, the parallel-resonant circuit 5-2 of the second matching circuit 8-2 is constructed by using the open and short stubs 14 and 15, not any chip devices, and the interdigital capacitor 22 is used as the series capacitor device 3 of the first matching circuit 8-1. Thus, no chip devices are present, and low-cost manufacturing can be facilitated. This advantage is very important for constructing the antenna apparatus by using the cylindrical dielectric 21.

In addition, the antenna apparatus of the ninth embodiment comprises the antenna 1 including the 4 helical radiation devices for radiating radio waves, the 4 impedance matching circuits 7 operable at the two frequencies f1 and f2, and the 4-distribution circuit 23, which are provided integrally on the cylindrical dielectric 21. Thus, it is possible to construct a compact radio terminal apparatus including the antenna apparatus.

Moreover, the antenna 1 has the 4 helical radiation devices, and there are 4 input terminals 2 of the antenna 1. However, because of the integral formation of the 4-distribution circuit 23, the number of the input terminals 25 of the antenna apparatus necessary for connection with the external circuit 10 is only 1. Thus, the structure of interface between the antenna apparatus and the external circuit 10 is simplified, making it possible not only to facilitate assembling and reducing costs, but also to improve reliability.

(Tenth Embodiment)

FIG. 42 is a perspective view showing an antenna apparatus according to the tenth embodiment of the invention. The antenna apparatus of the tenth embodiment comprises, in combination: an antenna as a 4-wire helical antenna provided on a hollow cylindrical dielectric; 4 impedance matching circuits respectively connected to 4 helical radiation devices, and adapted to operate the radiation devices at two frequency bands; and 4-distribution circuit respectively connected to the impedance matching circuits for distributing or synthesizing microwaves while generating a predetermined phase difference. The antenna and a power supply circuit are integrally provided. This antenna apparatus is used for a compact radio terminal such as a portable telephone set or the like. Each of the impedance matching circuits is different from that of the antenna apparatus of the ninth embodiment in that the one constructed by using the micro strip line, described above with reference to the seventh embodiment, is used.

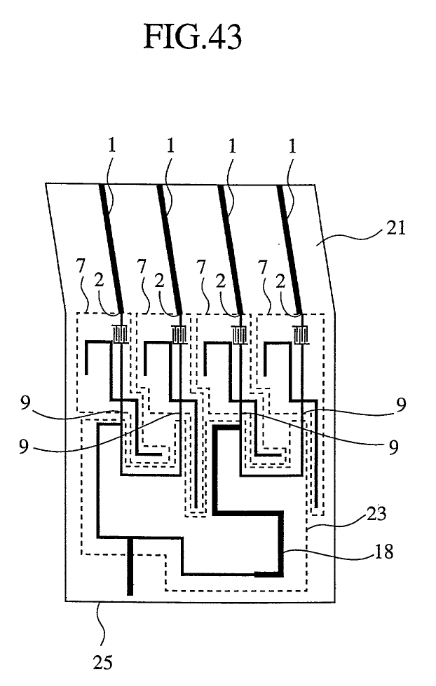

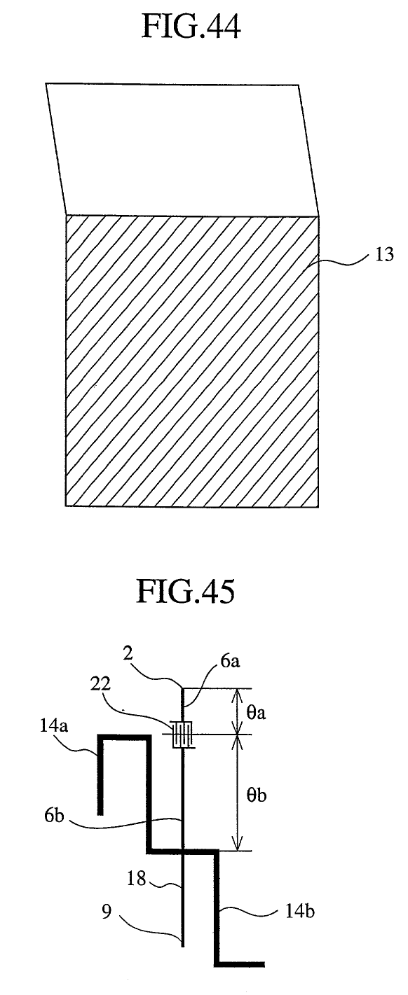

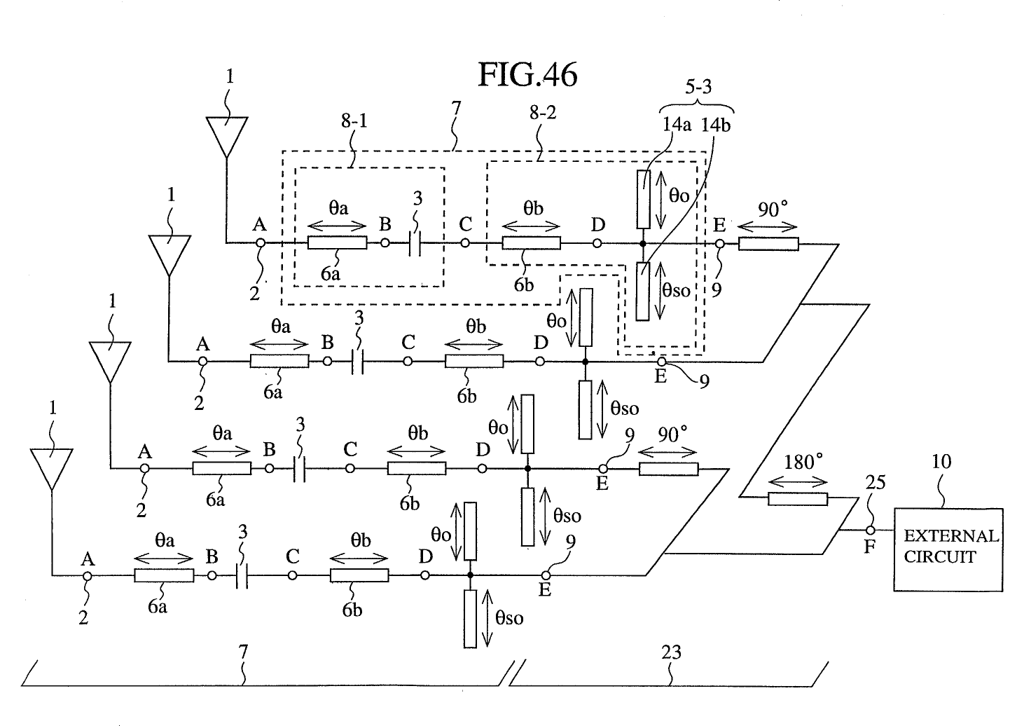

FIG. 43 is a development showing the cylindrical outer surface of the antenna apparatus shown in FIG. 42; FIG. 44 also a development showing the cylindrical inner surface of the same; FIG. 45 an expanded view showing a strip conductor pattern in the impedance matching circuit portion of the antenna apparatus; and FIG. 46 a circuit view of the antenna apparatus shown in FIG. 42.

In FIGS. 42 to 46, a reference numeral 21 denotes a hollow cylindrical dielectric; 1 an antenna including 4 helical radiation devices; 2 the input terminal of each of the helical radiation devices of the antenna 1; 13 a ground conductor; 18 a strip conductor constituting a micro strip line with the cylindrical dielectric 21 and the ground conductor 13; 6a a transmission line having an electrical length θa at the frequency f2; 22 an interdigital capacitor shown as a capacitor device 3 in the circuit view of FIG. 46; and 6b a transmission line having an electrical length θb at the frequency f1. These portions are similar to those of the antenna apparatus of the ninth embodiment shown in FIGS. 36 to 40, and are denoted by like reference numerals.

A reference numeral 14a denotes a first open stub as a micro strip line, having an electrical length θo; and 14b a second open stub as a micro strip line, having an electrical length θso. The first and second open stubs 14a and 14b are connected to the same place of the strip conductor 18 oppositely to each other.

A reference numeral 5-3 denotes a 1/2 wavelength resonant circuit including the first and second open stubs 14a and 14b, and adapted to function as a parallel-resonant circuit. In this case, the distribution of the electrical lengths θo and θso is decided such that parallel resonance can occur when a sum of the electrical lengths θo and θso of the first and second open stubs 14a and 14b is nearly equal to π at the frequency f2 (nearly equal to 1/2 of a wavelength at the frequency f2), and a predetermined susceptance value can be exhibited at the frequency f1. The sum of the electrical lengths θo and θso is normally set nearly equal to an integral multiple of a 1/2 wavelength at the frequency f2. In the described case, however, the sum is set nearly equal to 1/2 of the wavelength at the frequency f2 for the purpose of miniaturization. In accordance with this setting, a predetermined value is also set for the electrical length θb of the transmission line 6b.

A reference numeral 8-1 denotes a first matching circuit including the transmission line 6a and the interdigital capacitor 22, and adapted to perform impedance matching for the antenna 1 at the frequency f2; 8-2 a second matching circuit including the transmission line 6b and the 1/2 wavelength resonant circuit 5-3 having the first and second open stubs 14a and 14b constituting the micro strip line, and adapted to perform impedance matching at the frequency f1; and 7 an impedance matching circuit including the first and second matching circuits 8-1 and 8-2, and provided for performing impedance matching at the two frequencies f1 and f2. The prepared number of such impedance matching circuits 7 coincides with 4 in a corresponding relation to the helical radiation devices of the antenna 1. A reference numeral 9 denotes the input terminal of each of the 4 impedance matching circuits 7. Thus, each impedance matching circuit 7 is similar in configuration to the impedance matching circuit of the seventh embodiment.

A reference numeral 23 denotes a 4-distribution circuit including a micro strip line constructed by the cylindrical dielectric 21, the ground conductor 13 and the strip conductor 18, and having 4 distributing terminals respectively exhibiting required distribution amplitude and phase characteristics, the distributing terminals being respectively connected to the input terminals 9 of the 4 impedance matching circuits 7. The 4-distribution circuit 23 is adapted to generate a phase difference of nearly 90° among the 4 terminals. A reference numeral 25 denotes the input terminal of the 4-distribution circuit 23, which is also an input terminal of the antenna apparatus.

As in the case of the ninth embodiment, the ground conductor 13 is provided in a region in the inner surface of the cylindrical dielectric 21, which corresponds to a region having the strip conductor of the micro strip line constructing the impedance matching circuits 7 and the 4-distribution circuit 23 disposed in the outer surface thereof. A reference numeral 10 denotes an external circuit such as a power source circuit, an RF circuit or the like, connected to the input terminal 25 of the antenna apparatus constructed in the above manner.

In the circuit view of FIG. 46, the nodes A to F of the circuits are also shown for later operation description.

Next, the operation of the antenna apparatus will be described.

As in the former case, in the antenna apparatus of the tenth embodiment, power supply to the 4 helical radiation devices of the 4-wire helical antenna 1 is carried out by the 4-distribution circuit 23 based on a phase difference of 90°. In this case, the impedance matching circuit 7 matches the input impedance of the antenna 1 with the characteristic impedance of the external circuit 10. The operation of this impedance matching circuit 7 is similar to that of the ninth embodiment.

Specifically, the tenth embodiment is different from the ninth embodiment only in the following respect. That is, in the latter, the parallel-resonant circuit of the second matching circuit 8-2 is the 1/4 wavelength resonant circuit 5-2 including, in combination, the open and short stubs 14 and 15. In the former, the parallel-resonant circuit is the 1/2 wavelength resonant circuit 5-3 including, in combination, the first and second open stubs 14a and 14b. For this reason, in the tenth embodiment, the operation of the antenna 1 including the 4 helical radiation devices is similar to that of the ninth embodiment. Thus, the locus of active impedance when the antenna 1 side is seen from the input terminal 2 (node A) of the helical radiation device is similar to that shown in Smith chart of FIG. 8. As in the case of the ninth embodiment, the loci of impedance when the antenna 1 side is seen from the nodes B to E of FIG. 46 are similar to those shown in Smith charts of FIGS. 9 to 11, and 13.

As described above, in the antenna apparatus of the tenth embodiment, for the second matching circuit 8-2, the parallel-resonant circuit 5-3 including the first and second open stubs 14a and 14b is used. Thus, the through-hole 16 for connecting the short stub 15 to the ground conductor 13 is made unnecessary. Compared with the antenna apparatus of the ninth embodiment, which uses the parallel-resonant circuit 5-2 including the open and short stubs 14 and 15 for the second matching circuit 8-2, manufacturing can be facilitated more, and the antenna apparatus can be manufactured at lower costs.

As described above, the impedance matching circuit of the present invention includes the transmission line having a predetermined electrical length, connected to the antenna, and the parallel-resonant circuit connected in parallel with the transmission line, and adapted to resonate in parallel at the frequency f2 and exhibit a predetermined susceptance value at the lower frequency f1. This impedance matching circuit is applicable, when for the antenna in which an impedance matching has already been performed at the frequency f2, impedance is to be matched also with the characteristic impedance Z0 of the external circuit at the frequency f1 while the impedance matched state of the input terminal of the antenna at the frequency f2 is maintained. The impedance matching circuit is particularly advantageous in that the circuitry can be simplified and miniaturized, low costs can be achieved, reliability can be enhanced, and power consumption can be reduced.

The impedance matching circuit of the invention includes the first matching circuit interposed between the input terminal of the antenna and the second matching circuit to match the input impedance of the antenna at the frequency f2 with the characteristic impedance of the external circuit. This impedance matching circuit is applicable, when for the antenna in which an impedance matching has not been performed yet at the frequency f2, impedance is to be matched with the characteristic impedance Z0 not only at the frequency f2 but also at the frequency f1. The impedance matching circuit is particularly advantageous in that the circuitry can be simplified and miniaturized, low costs can be achieved, reliability can be enhanced, and power consumption can be reduced.

The impedance matching circuit of the invention includes the first matching circuit composed of the transmission line, and the capacitor device serially connected to the transmission line. The entire circuitry includes the capacitance device, the inductance device and the transmission line. This impedance matching circuit is applicable, when impedance matching is to be performed between the antenna and the external circuit at the two frequencies. The impedance matching circuit is particularly advantageous in that the circuitry can be simplified and miniaturized, and low costs can be achieved.

The impedance matching circuit of the invention includes the first matching circuit composed of the transmission line, and the inductance device serially connected to the transmission line. This impedance matching circuit is applicable, when impedance matching is to be performed at the two frequencies for the roughly 1/2 wavelength wire antenna or the like exhibiting a high input impedance characteristic. The impedance matching circuit is particularly advantageous in that it can be miniaturized.

The impedance matching circuit of the invention includes the first matching circuit composed of the transmission line, and the parallel-resonant circuit connected in parallel with the transmission line, and adapted to resonate in parallel at the frequency f1 and exhibit a predetermined susceptance value at the frequency f2. This impedance matching circuit is applicable, when impedance matching is to be performed at the two frequencies for antennas exhibiting all kinds of impedance characteristics.

The impedance matching circuit of the invention includes the second matching circuit composed of the transmission line having a predetermined electrical length, and the short and open stubs connected to this transmission line. The electrical lengths of the short and open stubs are set such that a sum of the electrical lengths of the short and open stubs can be set nearly equal to 1/4, or an odd number multiple, of a wavelength at the frequency f2, and a sum of susceptance values can take a predetermined susceptance value at the frequency f1. This impedance matching circuit has small losses and is applicable, when for the antenna in which an impedance matching has already been performed at the frequency f2, impedance is to be matched also with the characteristic impedance Z0 of the external circuit at the frequency f1 while the impedance matched state of the input terminal of the antenna at the frequency f2 is maintained. The impedance matching circuit is particularly advantageous in that the circuitry can be simplified and miniaturized, low costs can be achieved, reliability can be enhanced, and power consumption can be reduced.

The impedance matching circuit of the invention includes the first matching circuit interposed between the second matching circuit having the parallel-resonant circuit composed of the short and open stubs, and the input terminal of the antenna. The first matching circuit includes the transmission line having a predetermined electrical length, and the reactance device connected to this transmission line and adapted to match the input impedance of the antenna with the characteristic impedance of the external circuit. This impedance matching circuit has small losses and is applicable, when for the antenna in which an impedance matching has not been performed yet at the frequency f2, impedance is to be matched with the characteristic impedance Z0 not only at the frequency f2 but also at the frequency f1. The impedance matching circuit is particularly advantageous in that when the capacitor device is used for the reactance device, the entire circuit is constructed by one capacitance device and a transmission line, and thus the circuitry can be simplified, and in that when the inductance device is used, impedance matching can be performed for the antenna exhibiting a high input impedance characteristic.

The impedance matching circuit of the invention includes the transmission line, and the short and open stubs, constituting the planar transmission line such as a micro strip line. The capacitance device having the conductor pattern, such as an interdigital capacitor or the like, is used for the reactance device of the first matching circuit. This impedance matching circuit is constructed only by patterning the planar transmission line, and thus advantageous in that low-cost manufacturing can be realized.

The impedance matching circuit of the invention includes the first matching circuit composed of the transmission line having a predetermined electrical length, and the short and open stubs connected to this transmission line. The electrical lengths of the short and open stubs are set such that a sum of the electrical lengths thereof can be set nearly equal to 1/4, or an odd number multiple, of a wavelength at the frequency f1, and a sum of susceptance values can take a predetermined susceptance value at the frequency f2. The invention can be advantageously used for manufacturing the impedance matching circuit capable of performing impedance matching at the two frequencies for antennas exhibiting all kinds of impedance characteristics.

The impedance matching circuit of the invention includes the second matching circuit composed of the transmission line having a predetermined electrical length, and the first and second open stubs connected to this transmission line. The electrical lengths of the first and second open stubs are set such that a sum thereof can be set nearly equal to 1/2, or an integral multiple, of a wavelength at the frequency f2, and a sum of susceptance values can take a predetermined susceptance value at the frequency f1. This impedance matching circuit is applicable, when for the antenna in which an impedance matching has already been performed at the frequency f2, impedance is to be matched also with the characteristic impedance Z0 at the frequency f1 while the impedance matched state of the input terminal of the antenna at the frequency f2 is maintained. The invention is advantageous in that the impedance matching circuit including the parallel-resonant circuit composed of only the open stubs without using any through-holes can be manufactured easily and at low costs.

The impedance matching circuit of the invention includes the first matching circuit interposed between the second matching circuit having the parallel-resonant circuit composed of the first and second open stubs, and the input terminal of the antenna. The first matching circuit includes the transmission line having a predetermined electrical length, and the reactance device serially connected to this transmission line, and matches the input impedance of the antenna at the frequency f2 with the characteristic impedance of the external circuit. This impedance matching circuit is applicable, when for the antenna in which an impedance matching has not been performed at the frequency f2, impedance is to be matched with the characteristic impedance Z0 not only at the frequency f2 but also at the frequency f1. The impedance matching circuit is particularly advantageous in that when the capacitance device is used for the reactance device, the entire circuit is constructed by one capacitance device and a transmission line, and the circuitry can be simplified, and in that when the inductance device is used, impedance matching can be performed for the antenna exhibiting a high input impedance characteristic.

The impedance matching circuit of the invention includes the transmission line, and the first and second open stubs, constituting the planar transmission line such as a micro strip line or the like. The capacitance device having a conductor pattern, such as an interdigital capacitor or the like, is used for the reactance device of the first matching circuit. This impedance matching circuit is constructed only by patterning the planar transmission line, and thus advantageous in that low-cost manufacturing can be realized. The invention is particularly advantageous in that the impedance matching circuit including the parallel-resonant circuit constructed without using any through-holes can be manufactured easily and at low costs.

The impedance matching circuit of the invention includes the first matching circuit composed of the transmission line having a predetermined electrical length, and the first and second open stubs connected to this transmission line. The electrical lengths of the first and second open stubs are set such that a sum thereof can be set nearly equal to 1/2, or an integral multiple, of a wavelength at the frequency f1, and a sum of susceptance values can take a predetermined susceptance value at the frequency f2. This impedance matching circuit is applicable, when impedance matching is to be performed at the two frequency bands for antennas exhibiting all kinds of impedance characteristics. The invention is particularly advantageous in that the impedance matching circuit including the parallel-resonant circuit constructed without using any through-holes can be manufactured easily and at low costs.

The impedance matching circuit of the invention includes the first matching circuit composed of the impedance transformer, for matching the input impedance of the antenna with the characteristic impedance of the external circuit at the frequency f2. This impedance matching circuit is applicable, when impedance matching is to be performed at the two frequencies for the micro strip antenna.

The impedance matching circuit of the invention includes: the plurality of first matching circuits for performing impedance matching at the frequency f2, each having the strip conductor constituting the micro strip line with the cylindrical dielectric and the ground conductor, the transmission line and the capacitance device, and provided on the outer surface of the hollow cylindrical dielectric having the ground conductor formed in the inner surface; and the second matching circuits each having the transmission line and the parallel-resonant circuit adapted to resonate at the frequency f2 and exhibit a predetermined susceptance value at the frequency f1, and respectively connected to the first matching circuits. This invention is applicable for impedance matching circuits for the N-wire helical antenna, amounting to N in number and formed on the cylindrical dielectric only by patterning the strip conductor. The invention is particularly advantageous in that the impedance matching circuits can be manufactured easily and at low costs.

The impedance matching circuit of the invention includes the parallel-resonant circuit for each second matching circuit, which is composed of the short and open stubs connected to the transmission line. This invention is advantageously used for manufacturing the impedance matching circuit only by patterning the planar transmission line at low costs.

The impedance matching circuit of the invention includes the parallel-resonant circuit for each second matching circuit, which is composed of the first and second open stubs connected to the transmission line. This invention is advantageously used for manufacturing the impedance matching circuit only by patterning the planar transmission line at low costs. The invention is particularly advantageous in that the impedance matching circuit including the parallel-resonant circuit constructed without using any through-holes can be manufactured easily and at low costs.

The antenna apparatus of the invention is constructed in such a manner that the helical radiation devices composed of the strip-like conductors, amounting to N in number, are disposed on the outer surface of the hollow cylindrical dielectric having the ground conductor provided in the region as a part of the inner surface thereof, the impedance matching circuits having the first and second matching circuits, each composed of the strip conductor constituting the micro strip line with the cylindrical dielectric and the ground conductor, are disposed on the outer surface of the cylindrical dielectric corresponding to the respective helical radiation devices, and the impedance matching circuits are connected to the input terminal of the antenna apparatus via the N-distribution circuit constituting the micro strip line according to required distribution amplitude and phase characteristics. This invention is advantageously used for manufacturing the compact antenna apparatus comprising the helical radiation devices amounting to N in number, the impedance matching circuits and the N-distribution circuit integrally provided on the cylindrical dielectric. The invention is particularly advantageous in that the antenna apparatus having one input terminal for the helical radiation devices amounting to N in number, and the simple structure of interface with the external circuit can be assembled easily and manufactured at low costs to have high reliability.

The antenna apparatus of the invention comprises the parallel-resonant circuit for each impedance matching circuit, which includes the short and open stubs connected to the transmission line. This invention is advantageous in that the antenna apparatus comprising the plurality of helical radiation devices, the impedance matching circuits and the N-distribution circuit integrally provided on the cylindrical dielectric only by patterning the strip conductor can be manufactured easily and at low costs.

The antenna apparatus of the invention comprises the parallel-resonant circuit for each impedance matching circuit, which includes the first and second open stubs connected to the transmission line. This invention is applicable for manufacturing, easily and at low costs, the antenna apparatus comprising the plurality of helical radiation devices, the impedance matching circuits and the N distributing circuits integrally provided on the cylindrical dielectric only by patterning the strip conductor. The invention is particularly advantageous in that the impedance matching circuit including the parallel-resonant circuit constructed without using any through-holes can be manufactured easily and at low costs.

What is claimed is:

1. An impedance matching circuit for matching input impedance of an antenna and characteristic impedance of an external circuit with each other at two frequency bands, a frequency f1 and a higher frequency f2, comprising:
a transmission line having a predetermined electrical length, connected to the antenna in which an impedance matching has been performed at the frequency f2; and
a second matching circuit including a parallel-resonant circuit connected in parallel with said transmission line, and adapted to resonate at the frequency f2 and exhibit a predetermined susceptance value at the frequency f1.

2. The impedance matching circuit according to claim 1, further comprising: a first matching circuit interposed between an input terminal of the antenna and said second matching circuit to match the input impedance of the antenna and the characteristic impedance of the external circuit with each other at the frequency f2.

3. The impedance matching circuit according to claim 2, wherein said first matching circuit includes a transmission line having a predetermined electrical length, connected to the input terminal of the antenna, and a capacitance device connected in series to the transmission line.

4. The impedance matching circuit according to claim 2, wherein said first matching circuit includes a transmission line having a predetermined electrical length, connected to the input terminal of the antenna, and an inductance device connected in series to the transmission line.

5. The impedance matching circuit according to claim 2, wherein said first matching circuit includes a transmission line having a predetermined electrical length, connected to the input terminal of the antenna, and a parallel-resonant circuit connected in parallel with the transmission line, composed of inductance and capacitance devices connected in parallel with each other and adapted to resonate at the frequency f1 and exhibit a predetermined susceptance value at the frequency f2.

6. The impedance matching circuit according to claim 1, wherein said second matching circuit includes a transmission line having a predetermined electrical length, a short stub connected to the transmission line, and an open stub connected to the transmission line at a place substantially identical to that for the short stub, wherein electrical lengths of the short and open stubs are set such that a sum of the electrical lengths of the short and open stubs can be roughly 1/4, or an odd number multiple, of a wavelength at the frequency f2, and a sum of susceptance values of the short and open stubs can take a predetermined susceptance value at the frequency f1.

7. The impedance matching circuit according to claim 6, wherein a first matching circuit is interposed between an input terminal of the antenna and said second matching circuit to match the input impedance of the antenna and the characteristic impedance of the external circuit with each other at the frequency f2, said first matching circuit including a transmission line having a predetermined electrical length, and connected to the input terminal of the antenna, and a reactance device connected to the transmission line.

8. The impedance matching circuit according to claim 7, wherein for the reactance device of said first matching circuit, a capacitance device having a conductor pattern connected in series to the transmission line is used, and the transmission lines of said first and second matching circuits, and the short and open stubs are constructed by using a planar transmission line.

9. The impedance matching circuit according to claim 7, wherein said first matching circuit includes a transmission line having a predetermined electrical length, and connected to the input terminal of the antenna, a short stub connected to the transmission line, and an open stub connected to the transmission line at a place roughly identical to that for the short stub, and wherein electrical lengths of the short and open stubs are set such that a sum of the electrical lengths of the short and open stubs can be roughly 1/4, or an odd number multiple, of a wavelength at the frequency f1, and a sum of susceptance values of the short and open stubs can take a predetermined susceptance value at the frequency f2.

10. The impedance matching circuit according to claim 1, wherein said second matching circuit includes a transmission line having a predetermined electrical length, a first open stub connected to the transmission line, and a second open stub connected to the transmission line at a place roughly identical to that for the first open stub, and wherein electrical lengths of the first and second open stubs are set such that a sum of the electrical lengths of the first and second open stubs can be roughly 1/2, or an integral multiple, of a wavelength at the frequency f2, and a sum of susceptance values of the first and second open stubs can take a predetermined susceptance value at the frequency f1.

11. The impedance matching circuit according to claim 10, wherein a first matching circuit is interposed between an input terminal of the antenna and said second matching circuit to match the input impedance of the antenna and the characteristic impedance of the external circuit with each other at the frequency f2, said first matching circuit including a transmission line having a predetermined electrical length, connected to the input terminal of the antenna, and a reactance device connected to the transmission line.

12. The impedance matching circuit according to claim 11, wherein for the reactance device of said first matching circuit, a capacitance device having a conductor pattern connected in series to the transmission line is used, and the transmission lines of said first and second matching circuits, and the first and second open stubs are constructed by using a planar transmission line.

13. The impedance matching circuit according to claim 11, wherein said first matching circuit includes a transmission line having a predetermined electrical length, and connected to the input terminal of the antenna, a first open stub connected to the transmission line, and a second open stub connected to the transmission line at a place roughly identical to that for the first open stub, and wherein electrical lengths of the first and second open stubs are set such that a sum of the electrical lengths of the first and second open stubs can be roughly 1/2, or an integral multiple, of a wavelength at the frequency f1, and a sum of susceptance values of the first and second open stubs can take a predetermined susceptance value at the frequency f2.

14. The impedance matching circuit according to claim 10, wherein a first matching circuit is interposed between an input terminal of the antenna and said second matching circuit, said first matching circuit including a micro strip line, and an impedance transformer provided to match the input impedance of the antenna and the characteristic impedance of the external circuit with each other at the frequency f2.

15. An impedance matching circuit comprising:
a hollow cylindrical dielectric;
a ground conductor provided in a cylindrical inner surface of said cylindrical dielectric;
a plurality of first matching circuits disposed in a cylindrical outer surface of said cylindrical dielectric to perform impedance matching at a frequency f2, each of said first matching circuits including a strip conductor constituting a micro strip line with said ground conductor via said cylindrical dielectric, a transmission line, and a capacitance device; and
a plurality of second matching circuits disposed in the cylindrical outer surface of said cylindrical dielectric and respectively connected to said plurality of first matching circuits, each of said second matching circuits including the strip conductor, a transmission line, and a parallel-resonant circuit adapted to resonate at the frequency f2 and exhibit a predetermined susceptance value at a frequency f1.

16. The impedance matching circuit according to claim 15, wherein said parallel-resonant circuit includes a short stub connected to the transmission line, and an open stub connected to the transmission line at a place roughly identical to that for the short stub.

17. The impedance matching circuit according to claim 15, wherein said parallel-resonant circuit includes a first open stub connected to the transmission line, and a second open stub connected to the transmission line at a place roughly identical to that for the first open stub.

18. An antenna apparatus comprising:
a hollow cylindrical dielectric;
helical radiation devices amounting to N in number, including a strip-like conductor and helically wound on a cylindrical outer surface of said cylindrical dielectric;
a ground conductor provided in a region, the region being a part of a cylindrical inner surface of said cylindrical dielectric;
a strip conductor provided in the cylindrical inner surface of said cylindrical dielectric, constituting a micro strip line with said ground conductor via said cylindrical dielectric, and constituting a power supply line to each of said helical radiation devices;
impedance matching circuits amounting to N in number, respectively connected to said helical radiation devices, each of said impedance matching circuits including a first matching circuit having the strip conductor, a transmission line and a capacitance device, and adapted to perform impedance matching at a frequency f2, and a second matching circuit connected to the first matching circuit, the second matching circuit having the strip conductor, a transmission line, and a parallel-resonant circuit adapted to resonate at the frequency f2 and exhibit a predetermined susceptance value at a frequency f1; and
an N-distribution circuit including the strip conductor, wherein said N-distribution circuit comprises distributing terminals amounting to N in number exhibiting required distribution amplitude and phase characteristics, said distributing terminals being respectively connected to input terminals of said impedance matching circuits amounting to N in number.

19. An antenna apparatus according to claim 18, wherein the parallel-resonant circuit of said impedance matching circuit includes a short stub connected to the transmission line, and an open stub connected to the transmission line at a place roughly identical to that for the short stub.

20. An antenna apparatus according to claim 18, wherein the parallel-resonant circuit of said impedance matching circuit includes a first open stub connected to the transmission line, and a second open stub connected to the transmission line at a place roughly identical to that for the first open stub.
